(19) United States
(12) Patent Application Publication
(10) Pub. No.: US 2026/0026031 A1
(43) Pub. Date: Jan. 22, 2026

(54) ELECTROSTATIC DISCHARGE PROTECTION DEVICE AND METHODS OF FORMATION

(71) Applicant: Taiwan Semiconductor Manufacturing Company, Ltd., Hsinchu (TW)

(72) Inventors: Lin-Yu HUANG, Hsinchu (TW); Shih-Fan CHEN, Hsinchu City (TW); Sheng-Fu HSU, Hsinchu (TW); Yu-Chang JONG, Hsinchu City (TW)

(21) Appl. No.: 18/774,281

(22) Filed: Jul. 16, 2024

(51) Int. Cl. H01L 29/78; H01L 21/308; H01L 21/311; H01L 27/02; H01L 29/06; H01L 29/08; H01L 29/423; H01L 29/66

(52) U.S. Cl. CPC H10D 30/601; H01L 21/308; H01L 21/31111; H10D 62/10; H10D 62/151; H10D 64/017; H10D 64/512; H10D 64/514; H10D 89/811

(57) ABSTRACT

A semiconductor device includes an electrostatic discharge (ESD) protection device that includes an active gate structure and a plurality of dummy gate structures between the active gate structure and a source/drain region if the ESD protection device. The dummy gate structures are used as a self-aligned implant mask when forming the source/drain region. The dummy gate structures enable the source/drain region to be formed as a plurality of implant segments that are spaced apart in a substrate of the semiconductor device. The space between the implant segments provides areas in the substrate in which dopants from the implant segments may diffuse from subsequent manufacturing operations for the semiconductor device. Thus, the dopants diffuse into the substrate across a greater area of the substrate than if the source/drain region were a continuous implant region, reducing the dopant concentration from the implant segments in the substrate.

### BACKGROUND

Electrostatic discharge (ESD) is a concern for semiconductor integrated circuits (ICs). If not handled properly, an ESD event can result in a high voltage that may damage device circuitry of a semiconductor device. To prevent ESD-related damage, a semiconductor device may include an ESD protection circuit. The ESD protection circuit may be operable to divert electrical current away from device circuitry of the semiconductor device during an ESD event, thereby protecting the device circuitry from being damaged by the ESD event.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1C are diagrams of an example semiconductor device described herein.

FIGS. 2A-2E are diagrams of example implementations of gate structures included in an electrostatic discharge (ESD) protection device described herein.

FIGS. 3A-3H are diagrams of an example implementation of ESD protection structures of a semiconductor device described herein.

FIGS. 4A-4G are diagrams of an example implementation of forming gate structures of an ESD protection device described herein.

FIGS. 5A-5K are diagrams of an example implementation of forming an interconnect layer of a semiconductor device described herein.

FIGS. 6A and 6B are diagrams of an example semiconductor device described herein.

FIGS. 7A-7D are diagrams of an example semiconductor device described herein.

FIGS. 8A-8C are diagrams of an example semiconductor device described herein.

FIG. 9 is a diagram of an example semiconductor device described herein.

FIG. 10 is a flowchart of an example process associated with forming an ESD protection device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An electrostatic discharge (ESD) protection device may be included between regions of a semiconductor device to provide ESD protection for ESD events that might otherwise propagate between the regions of the semiconductor device. For example, an ESD protection device may be included between an input/output (I/O) region and a core integrated circuit (IC) region to protect the core IC region from ESD events that enter the semiconductor device through the I/O region.

The ESD protection device may include one or more grounded-gate metal-oxide-semiconductor field effect transistors (MOSFETs) such as a grounded-gate n-type MOSFET (ggNMOS) device and/or a grounded-gate p-type MOSFET (ggPMOS) device. Grounded-gate ESD protection devices have advantages including low trigger voltage, low power dissipation, and full compatibility with BCD (bipolar/complementary-metal-oxide-semiconductor (CMOS)/double diffused metal-oxide-semiconductor (DMOS)) technology. As indicated by the name, the gate structure of a grounded-gate MOSFET is electrically grounded. A source/drain region of the grounded-gate MOSFET is electrically connected to the I/O region. When an ESD event such as a voltage spike occurs, a high voltage is applied to the source/drain region, which causes a low impedance path to be formed between the source/drain region and electrical ground. Thus, the grounded-gate MOSFET effectively clamps the voltage at the source/drain region to a safe level, thereby protecting the core IC region from being damaged by the voltage spike.

An ESD protection device may be designed and manufactured to satisfy one or more ESD protection requirements or standards according to an ESD model, such as the human body model (HBM). Here, the ESD protection device needs to survive and provide ESD protection at particular voltage levels for particular durations of time in order to be certified as satisfying the one or more ESD protection requirements or standards.

In some cases, repeated exposure to ESD events can cause an ESD protection device to become damaged, resulting in failure of the ESD protection device. For example, dopant concentration in a substrate of the ESD protection device near the gate structure of a grounded-gate MOSFET may result in an electrical field in the substrate being concentrated at an interface between a p-doped region and an n-dope region in the substrate near the gate structure. The strength of the electric field at the interface, resulting from the concentration of p-type and n-type dopants, may accelerate the damage caused to the ESD protection device, thereby leading to accelerated burnout and failure of the ESD protection device.

In some implementations described herein, a semiconductor device includes an ESD protection device that includes an active gate structure and a plurality of dummy gate structures between the active gate structure and a source/drain region of the ESD protection device. The dummy gate structures are used as a self-aligned implant mask when forming the source/drain region. The dummy gate structures enable the source/drain region to be formed as a plurality of non-contiguous implant segments that are spaced apart in a substrate of the semiconductor device. The space between the non-contiguous implant segments provides areas in the substrate in which dopants from the non-contiguous implant segments may diffuse from subsequent manufacturing operations for the semiconductor device. Thus, the dopants diffuse into the substrate across a greater area of the substrate than if the source/drain region were a continuous implant region, reducing the dopant concentration from the implant segments in the substrate. This reduces the build-up and concentration of dopants near the active gate structure, which reduces the strength of the electric field near the active gate structure. The reduced strength of the electric field near the active gate structure lessens the damage caused to the ESD protection device across multiple ESD events, thereby increasing the operational life of the ESD protection device.

The inclusion of dummy gate structures in the ESD protection device provides additional improvements to the ESD protection device, such as increased gate density in the ESD protection device and increased gate-to-source/drain spacing in the ESD protection device. The increased gate density reduces the magnitude of dishing in a dielectric layer surrounding the active gate structure and the dummy gate structures, which reduces the likelihood of (and/or reduces the amount of) accumulation of residual materials on the dielectric layer. The reduced likelihood of (and/or the reduced amount of) accumulation of residual materials on the dielectric layer reduces the likelihood of under-etching when etching through the dielectric layer to form source/drain recesses for the source/drain regions of the ESD protection device. Thus, the reduction in dishing in the dielectric layer reduces the likelihood of a disconnect between the source/drain regions and source/drain contacts formed in the source/drain recesses.

The inclusion of the dummy gate structures in the ESD protection device enables an increased gate-to-source/drain spacing to be achieved in the ESD protection device in that the increased density of gate structures in the ESD protection device enables a masking layer for patterning the gate dielectric layers of the active gate structure and the dummy gate structures to be formed to a greater thickness than if the dummy gate structures were not included. The greater thickness of the masking layer reduces the amount of lateral etching of the masking layer when patterning the masking layer, resulting in a greater lateral width of the remaining portions of the masking layer over the active gate structure. The greater lateral width of the remaining portions of the masking layer over the active gate structure enables the gate dielectric layer of the active gate structure to be formed using the masking layer such that the gate dielectric layer laterally extends outward from the active gate structure. When the gate dielectric layers of the active gate structure and of the dummy gate structures are then used as part of the self-aligned implant mask to form the non-contiguous implant segments of the source/drain region, the lateral extensions of the gate dielectric layer of the active gate structure enable a greater spacing between the active gate structure and the implant segment closest to the active gate structure to be achieved, thereby enabling a greater gate-to-source/drain spacing to be achieved. The greater gate-to-source/drain spacing reduces the amount of gate-induced drain leakage (GIDL) that occurs between the active gate structure and the source/drain region.

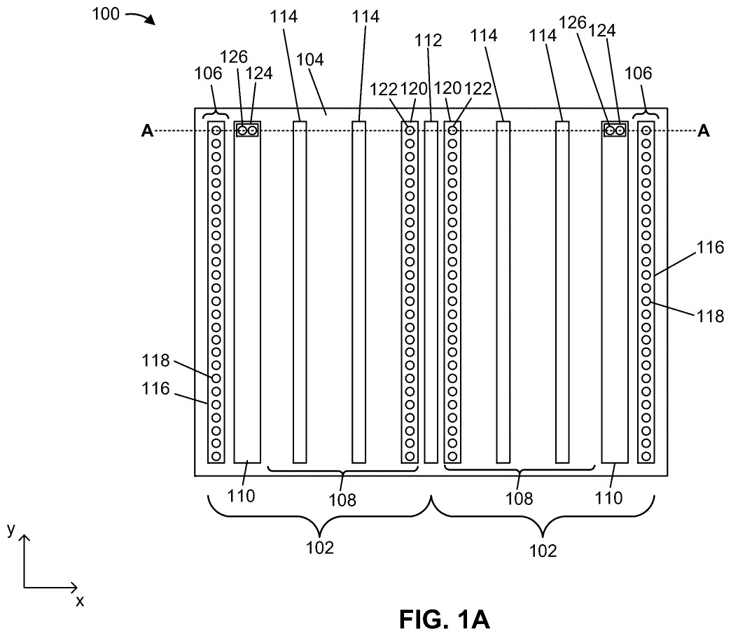

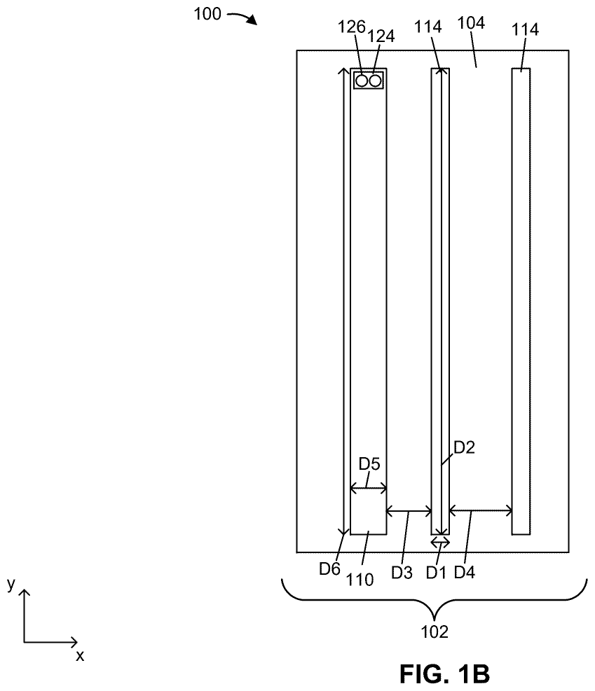

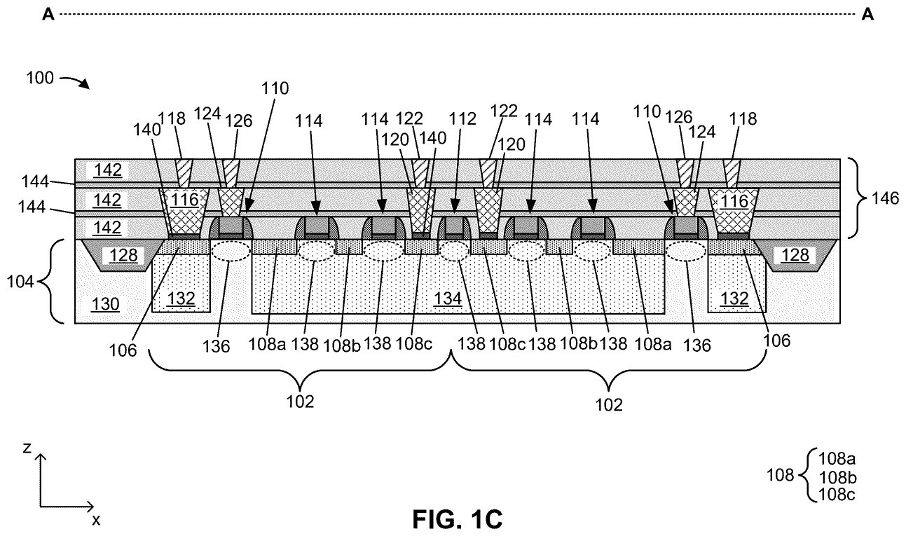

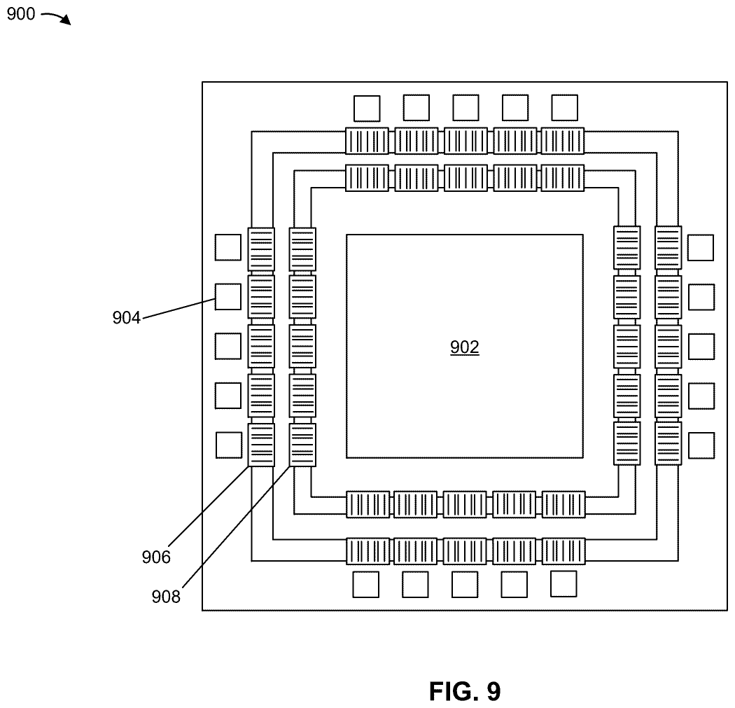

FIGS. 1A-1C are diagrams of an example semiconductor device 100 described herein. FIG. 1A illustrates a top view of the semiconductor device 100. As shown in FIG. 1A, the semiconductor device 100 includes one or more ESD protection devices 102. One or more of the semiconductor devices 100 may be included in another semiconductor device, such as a semiconductor device 900 of FIG. 9, to provide ESD protection for integrated circuit devices of the other semiconductor device.

As shown in FIG. 1A, the semiconductor device 100 includes a substrate 104 on which the one or more ESD protection devices 102 may be formed. The substrate 104 may include a silicon (Si) substrate, a substrate formed of a material including silicon, a III-V compound semiconductor material substrate such as gallium arsenide (GaAs), a silicon on insulator (SOI) substrate, a germanium (Ge) substrate, a silicon germanium (SiGe) substrate, a silicon carbide (SiC) substrate, or another type of semiconductor substrate. The substrate 104 may include various layers, including conductive or insulating layers formed on a semiconductor substrate. The substrate 104 may include a compound semiconductor and/or an alloy semiconductor. The substrate 104 may include various doping configurations to satisfy one or more design parameters. For example, different doping profiles (e.g., n-wells, p-wells) may be formed on the substrate 104 in regions designed for different device types (e.g., p-type metal-oxide-semiconductor (PMOS) nanostructure transistors, n-type metal-oxide-semiconductor (NMOS) nanostructure transistors). The suitable doping may include ion implantation of dopants and/or diffusion processes. Further, the substrate 104 may include an epitaxial layer (epi-layer), may be strained for performance enhancement, and/or may have other suitable enhancement features. The substrate 104 may include a portion of a semiconductor wafer on which other semiconductor devices are formed.

As further shown in FIG. 1A, an ESD protection device 102 includes a source/drain region 106 and a source/drain region 108 in the substrate 104, and an active gate structure 110 between the source/drain regions 106 and 108. The source/drain region 106, the source/drain region 108, and the active gate structure 110 are arranged in an x-direction in the semiconductor device 100 and may extend approximately parallel to each other in the y-direction in the semiconductor device 100. The source/drain region 106 may be located adjacent to a first side of active gate structure 110, and the source/drain region 108 may be located adjacent to a second side of the active gate structure 110 opposing the first side.

An ESD protection device 102 may correspond to a grounded-gate MOSFET or another type of ESD protection transistor structure. The active gate structure 110 corresponds to the active gate of the grounded-gate MOSFET (e.g., the gate structure that is operational and connected to back end circuitry in the semiconductor device 100), and the source/drain regions 106 and 108 correspond to the source/drain regions of the grounded-gate MOSFET. A “Source/drain region” may refer to a source or a drain, individually or collectively, depending upon the context. In some implementations, the source/drain region 106 is a source region of the grounded-gate MOSFET, and the source/drain region 108 is a drain region of the grounded-gate MOSFET. The grounded-gate MOSFET may be a planar transistor, a fin field effect transistor (finFET), a nanostructure (e.g., a gate all around (GAA) transistor, a nanowire transistor, a nanosheet transistor, a multi-bridge channel transistor, a nanoribbon transistor), and/or another type of transistor structure. In some implementations, the source/drain region 108 may be electrically connected to an I/O integrated circuit device of another semiconductor device in which the semiconductor device 100 is included.

As further shown in FIG. 1A, the semiconductor device 100 includes a plurality of dummy gate structures. For example, a dummy gate structure 112 may be included between adjacent source/drain regions 108 of adjacent ESD protection devices 102 in the semiconductor device 100. As another example, a plurality of dummy gate structures 114 may be included above the source/drain region 108 and between the active gate structure 110 and the dummy gate structure 112. The dummy gate structures 112 and 114 are non-active gate structures that are non-operational in the semiconductor device 100, and in some implementations are not connected to back end circuitry in the semiconductor device 100. The dummy gate structures 112 and 114 are “gate structures” in that the dummy gate structures 112 and 114 are formed during the same processes as the active gate structures 110 of the ESD protection devices 102. The dummy gate structures 112 and 114 each extend in the y-direction and approximately parallel to the active gate structure 110. The active gate structure 110, the dummy gate structure 112, and the dummy gate structures 114 are arranged in the x-direction in the semiconductor device 100.

As further shown in FIG. 1A, a source/drain contact 116 is included on and electrically connected with the source/drain region 106, and one or more source/drain interconnects 118 are included on and electrically connected with the source/drain contact 116. Similarly, a source/drain contact 120 is included on and electrically connected with the source/drain region 108, and one or more source/drain interconnects 122 are included on and electrically connected with the source/drain contact 120. In some implementations, the source/drain contacts 116 and 120 are each elongated conductive structures that extend in the y-direction. The source/drain interconnects 118 may be arranged in the y-direction along the source/drain contact 116, and the source/drain interconnects 122 may be arranged in the y-direction along the source/drain contact 120. A gate contact 124 may be included on an end of the active gate structure 110, and one or more gate interconnects 126 may be included on and electrically connected with the gate contact 124.

FIG. 1B illustrates various dimensions of an ESD protection device 102. An example dimension D1 includes an x-direction length of a dummy gate structure 114. In some implementations, the dimension D1 is included in a range of approximately 5 nanometers to approximately 1,000 nanometers. If the dimension D1 is less than approximately 5 nanometers, the gap-filling performance when forming the dummy gate structures 114 may be insufficient to achieve void-free formation of the dummy gate structures 114, and therefore voids may be formed in the dummy gate structures 114. If the dimension D1 is greater than approximately 1,000 nanometers, insufficient on current (Iₒₙ) may be achieved for the ESD protection circuit. If the dimension D1 is included in the range of approximately 5 nanometers to approximately 1,000 nanometers, the dummy gate structures 114 may be formed with few to no voids while enabling a sufficiently high on current to be achieved for the ESD protection device 102. However, other values and ranges, other than approximately 5 nanometers to approximately 1,000 nanometers, for the dimension D1 are within the scope of the present disclosure.

Another example dimension D2 includes a y-direction width of a dummy gate structure 114. In some implementations, the dimension D2 is included in a range of approximately 0.1 microns to approximately 40 microns. If the dimension D2 is less than approximately 0.1 microns, dishing may occur in a dielectric layer surrounding the dummy gate structures 114, which may result in an increased likelihood of residual material being retained on the dielectric layer (which may cause under-etching when forming recesses for the source/drain contacts 116 and 120). If the dimension D2 is greater than approximately 40 microns, the dummy gate structure 114 may occupy too large of an area in the semiconductor device 100 and may decrease device density. If the dimension D2 is included in the range of approximately 0.1 microns to approximately 40 microns, a high device density may be achieved in the semiconductor device 100 while enabling a sufficiently low likelihood of dishing to be achieved in the semiconductor device 100. However, other values and ranges, other than approximately 0.1 microns to approximately 40 microns, for the dimension D2 are within the scope of the present disclosure.

Another example dimension D3 includes an x-direction distance or spacing between the active gate structure 110 and the dummy gate structure 114 closest to the active gate structure 110. In some implementations, the dimension D3 is included in a range of approximately 20 nanometers to approximately 8,000 nanometers. If the dimension D3 is less than approximately 20 nanometers, insufficient space above the active gate structure 110 may be provided for the gate contact 124 of the active gate structure 110, which can lead to shorting between the active gate structure 110 and the dummy gate structure 114 closest to the active gate structure 110. If the dimension D3 is greater than approximately 8,000 nanometers, dishing may occur in a dielectric layer surrounding the active gate structure 110 and the dummy gate structures 114, which may result in an increased likelihood of residual material being retained on the dielectric layer (which may cause under-etching when forming recesses for the source/drain contacts 116 and 120). If the dimension D3 is included in the range of approximately 20 nanometers to approximately 8,000 nanometers, sufficient space above the active gate structure 110 may be provided for the gate contact 124 of the active gate structure 110, and a sufficiently low likelihood of dishing may be achieved in the semiconductor device 100. However, other values and ranges, other than approximately 20 nanometers to approximately 8,000 nanometers, for the dimension D3 are within the scope of the present disclosure.

Another example dimension D4 includes an x-direction distance or spacing between adjacent the dummy gate structures 114. In some implementations, the dimension D4 is included in a range of approximately 20 nanometers to approximately 8,000 nanometers. If the dimension D4 is less than approximately 20 nanometers, insufficient space above the active gate structure 110 may be provided for the source/drain contact 120 of the source/drain region 108, which can lead to shorting between the source/drain contact 120 and the dummy gate structure 114 closest to the source/drain contact 120. If the dimension D4 is greater than approximately 8,000 nanometers, dishing may occur in a dielectric layer surrounding the dummy gate structures 114, which may result in an increased likelihood of residual material being retained on the dielectric layer (which may cause under-etching when forming recesses for the source/drain contacts 116 and 120). If the dimension D4 is included in the range of approximately 20 nanometers to approximately 8,000 nanometers, sufficient space above the active gate structure 110 may be provided for the gate contact 124 of the active gate structure 110, and a sufficiently low likelihood of dishing may be achieved in the semiconductor device 100. However, other values and ranges, other than approximately 20 nanometers to approximately 8,000 nanometers, for the dimension D4 are within the scope of the present disclosure.

An example dimension D5 includes an x-direction length of the active gate structure 110. In some implementations, the dimension D5 is included in a range of approximately 10 nanometers to approximately 1,000 nanometers. If the dimension D5 is less than approximately 10 nanometers, the active gate structure 110 may be unable to sufficiently control the operation of the ESD protection device 102. If the dimension D5 is greater than approximately 1,000 nanometers, the triggering speed for the ESD protection device 102 may be too low. If the dimension D5 is included in the range of approximately 10 nanometers to approximately 1,000 nanometers, sufficient gate control and fast operating speeds may be achieved for the ESD protection device 102. However, other values and ranges, other than approximately 10 nanometers to approximately 1,000 nanometers, for the dimension D5 are within the scope of the present disclosure.

Another example dimension D6 includes a y-direction width of the active gate structure 110. In some implementations, the dimension D6 is included in a range of approximately 2 microns to approximately 40 microns. If the dimension D6 is less than approximately 2 microns, dishing may occur in a dielectric layer surrounding the dummy gate structures 114, which may result in an increased likelihood of residual material being retained on the dielectric layer (which may cause under-etching). If the dimension D6 is greater than approximately 40 microns, the active gate structure 110 may occupy too large of an area in the semiconductor device 100 and may decrease device density. If the dimension D6 is included in the range of approximately 2 microns to approximately 40 microns, a high device density may be achieved in the semiconductor device 100 while enabling a sufficiently low likelihood of dishing to be achieved in the semiconductor device 100. However, other values and ranges, other than approximately 2 microns to approximately 40 microns, for the dimension D6 are within the scope of the present disclosure.

Other example dimensions for the ESD protection device 102 include a substrate area (e.g., an area of the substrate 104 in which the ESD protection device 102 is included), which may be included in a range of approximately 30 square microns to approximately 1,000 square microns, and a quantity of dummy gate structures 114. A greater quantity of dummy gate structures 114 may reduce the amount of dishing in the dielectric layer around the dummy gate structures 114, whereas a lesser quantity of dummy gate structures 114 may enable the dummy gate structures 114 to be spaced further apart, thereby providing more area in the substrate 104 for dopant diffusion from the discontinuous implant segments of the source/drain region 108. The quantity of dummy gate structures 114 may be an even quantity or an odd quantity. In some implementations, a single dummy gate structure 114 is included between the active gate structure 110 and the dummy gate structure 112.

FIG. 1C illustrates a cross-section view of the semiconductor device 100 along the line A-A in FIG. 1A. As shown in FIG. 1C, the semiconductor device 100 may include a plurality of shallow trench isolation (STI) regions 128 in the substrate 104 at opposing ends of the ESD protection devices 102. The STI regions 128 may include a dielectric material such as a silicon oxide (SiOₓ), a silicon nitride (SiₓN_{y}), a silicon oxynitride (SiON), fluoride-doped silicate glass (FSG), a low dielectric constant (low-k) dielectric material, and/or another suitable insulating material. The STI regions 128 may include a multi-layer structure, for example, having one or more liner layers.

As further shown in FIG. 1C, an ESD protection device 102 may include a plurality of doped regions that are included in the substrate 104. For example, an ESD protection device 102 may include a well region 130 in the substrate 104. The well region 130 may include a first dopant type. For example, the well region 130 may include a p-doped well that includes one or more p-type dopants, such as boron (B), gallium (Ga), and/or indium (In), among other examples.

As another example, an ESD protection device 102 may include a plurality of implant regions in the well region 130, such as a lightly doped implant region 132 and a lightly doped implant region 134. The lightly doped implant regions 132 and 134 may each include the same dopant type, such as an n-type dopant. Examples of n-type dopants include phosphorous (P), arsenic (As), bismuth (Bi), and/or stibium (Sb), among other examples. The dopant type of the lightly doped implant regions 132 and 134 may be different from the dopant type of the well region 130.

As another example, an ESD protection device 102 may include a plurality of source/drain implant regions above the lightly doped implant regions 132 and 134, such as an implant region corresponding to the source/drain region 106 and a plurality of discontinuous implant segments 108a-108c corresponding to the source/drain region 108. The source/drain region 106 and the discontinuous implant segments 108a-108c may include the same dopant type, which may be the same dopant type as the lightly doped implant regions 132 and 134. For example, the source/drain region 106 and the discontinuous implant segments 108a-108c may each include n-type dopants such as phosphorous (P), arsenic (As), bismuth (Bi), and/or stibium (Sb), among other examples. However, the dopant concentration in the source/drain region 106 and the discontinuous implant segments 108a-108c of the source/drain region 108 may be greater than the dopant concentration in the lightly doped implant regions 132 and 134. The lightly doped implant region 132 may be referred to as a lightly doped drain (LDD) region of the source/drain region 106, and the lightly doped implant region 134 may be referred to as an LDD region of the source/drain region 108.

A channel region 136 of an ESD protection device 102 is included in a portion of the well region 130 under the active gate structure 110 and between the source/drain regions 106 and 108. In some implementations, the source/drain regions 106 and 108 are n-doped regions and the well region 130 is a p-doped region. In these implementations, the ESD protection device 102 may be referred to as an NPN (or NMOS) ESD protection device 102 in that an n-doped region/p-doped region/n-doped region arrangement is formed by the source/drain region 106, the channel region 136, and the source/drain region 108. In some implementations, the source/drain regions 106 and 108 are p-doped regions and the well region 130 is an n-doped region. In these implementations, the ESD protection device 102 may be referred to as a PNP (or PMOS) ESD protection device 102 in that a p-doped region/n-doped region/p-doped region arrangement is formed by the source/drain region 106, the channel region 136, and the source/drain region 108.

As further shown in FIG. 1C, the dummy gate structures 114 are included between adjacent pairs of the discontinuous implant segments 108a-108c of the source/drain region 108. The dummy gate structures 114 are used as a self-aligned implant mask for forming the discontinuous implant segments 108a-108c. Thus, the discontinuous implant segments 108a-108c are omitted from the regions of the substrate 104 under the dummy gate structures 114, resulting in spaces between the discontinuous implant segments 108a-108c. The spaces between the discontinuous implant segments 108a-108c correspond to diffusion regions 138 under the dummy gate structures 114. Another diffusion region 138 is included under the dummy gate structure 112 between adjacent ESD protection devices 102. The diffusion regions 138 provide regions in the substrate 104 for diffusion of dopants from the discontinuous implant segments 108a-108c. This enables the dopants to laterally diffuse from the discontinuous implant segments 108a-108c into the diffusion regions 138, as opposed to the dopants building up along the edge of the lightly doped implant region 134 adjacent to the channel region 136 under the active gate structure 110. This inhibits an electric field in an ESD protection device 102 from building up at the interface between the lightly doped implant region 134 and the channel region 136, which might otherwise cause premature burnout of the ESD protection device 102.

The discontinuous implant segments 108a-108c may extend in the y-direction in the substrate 104 alongside the dummy gate structures 114. The quantity of implant segments included in the discontinuous implant segments 108a-108c of an ESD protection device 102 may be based on the quantity of dummy gate structures 114 included in the ESD protection device 102. The quantity of discontinuous implant segments 108a-108c illustrated in FIG. 1C is an example, and other quantities are within the scope of the present disclosure.

As further shown in FIG. 1C, the source/drain contact 116 may be included on and electrically connected to the source/drain region 106, and the source/drain interconnects 118 may be included on and electrically connected to the source/drain contact 116. Similarly, the source/drain contact 120 may be included on and electrically connected to the source/drain region 108, and the source/drain interconnects 122 may be included on and electrically connected to the source/drain contact 120. In particular, the source/drain contact 120 and the associated source/drain interconnects 122 may be included on the implant segment 108c furthest away from the active gate structure 110, to reduce and/or minimize the likelihood of gate-to-drain shorting. Alternatively, source/drain contact 120 is included on another implant segment of the source/drain region. In particular, the source/drain contact 120 and the associated source/drain interconnects 122 may be included on another implant segment of the source/drain region 108, such as the implant segment 108a or the implant segment 108b, among other examples.

The gate contact 124 may be included on and electrically connected with the active gate structure 110, and the gate interconnects 126 may be included on and electrically connected with the gate contact 124. In some implementations, silicide layers 140 are included between source/drain region 106 and the source/drain contact 116 and/or between the source/drain region 108 and the source/drain contact 120. The silicide layers 140 may be included to reduce contact resistance between the source/drain region 106 and the source/drain contact 116 and/or between the source/drain region 108 and the source/drain contact 120. A silicide layer 140 may include a metal silicide such as titanium silicide (TiSi), ruthenium silicide (RuSi), and/or another suitable metal silicide material.

As further shown in FIG. 1C, the source/drain contact 116, the source/drain interconnects 118, the source/drain contact 120, the source/drain interconnects 122, the gate contact 124, and the gate interconnect 126 may be included in and may extend through a plurality of dielectric layers above the substrate 104. The dielectric layers may include interlayer dielectric (ILD) layers 142 and etch stop layers (ESLs) 144, among other examples. The dielectric layers and the source/drain contact 116, the source/drain interconnects 118, the source/drain contact 120, the source/drain interconnects 122, the gate contact 124, and the gate interconnect 126 may correspond to an interconnect layer 146 of the semiconductor device 100. The interconnect layer 146 may also be referred to as a back end region or back end of line (BEOL) region of the semiconductor device 100. The ILD layers 142 and the ESLs 144 may each include one or more dielectric materials, such as an oxide (e.g., a silicon oxide (SiOₓ) and/or another oxide material), an undoped silicate glass (USG), a boron-containing silicate glass (BSG), a fluorine-containing silicate glass (FSG), an extreme low dielectric constant (ELK) dielectric material having a dielectric constant that is less than approximately 2.5, a silicon nitride (SiₓN_{y}), silicon carbide (SiC), silicon oxynitride (SiON), and/or another suitable dielectric material.

As indicated above, FIGS. 1A-1C are provided as examples. Other examples may differ from what is described with regard to FIGS. 1A-1C.

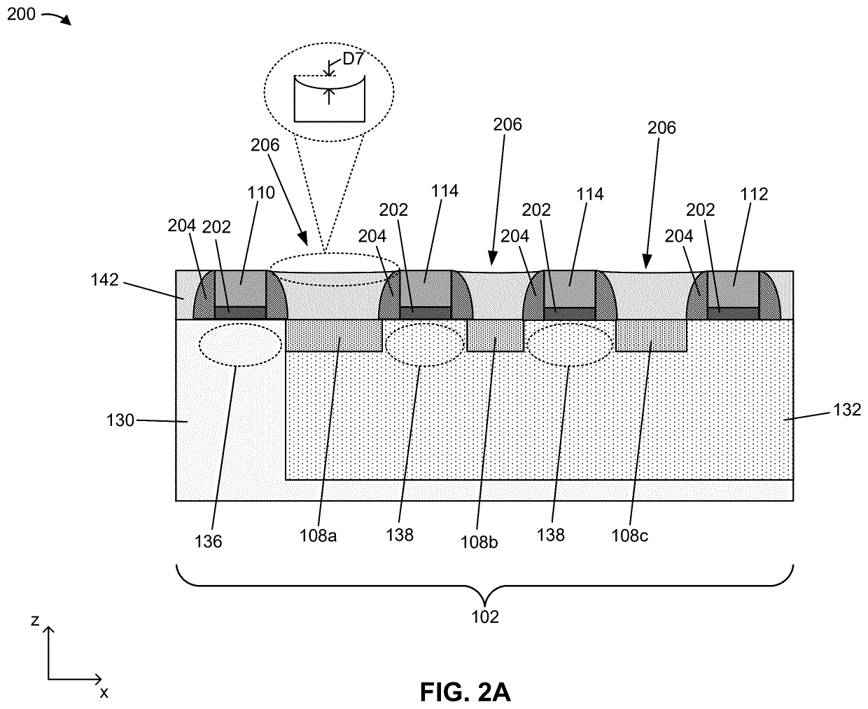

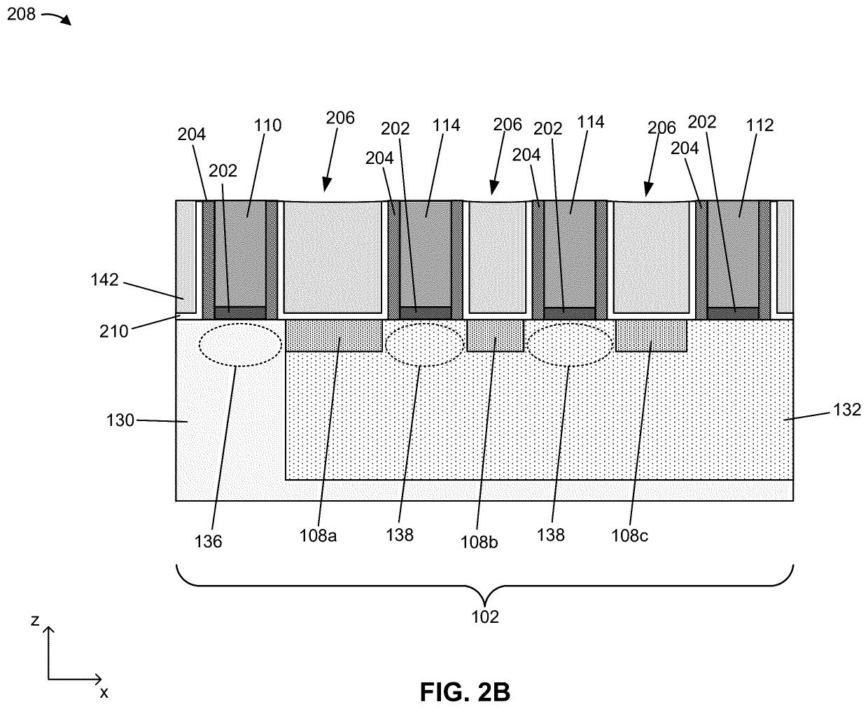

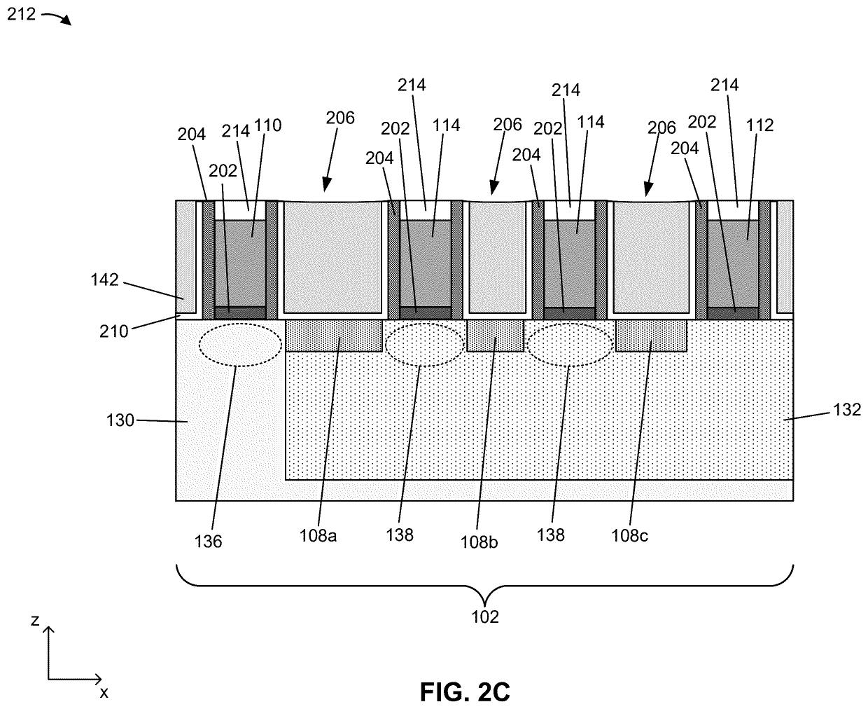

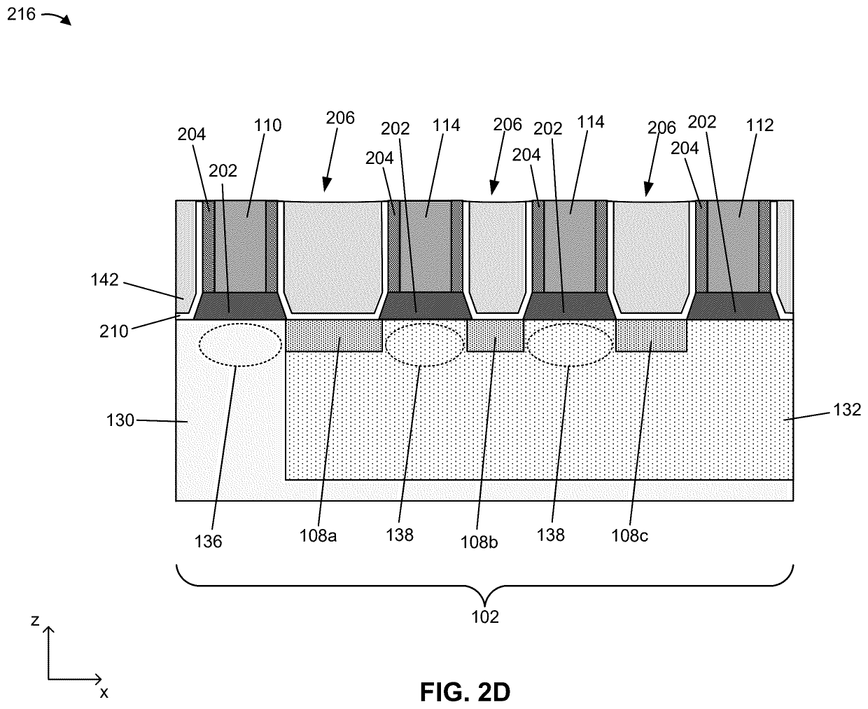

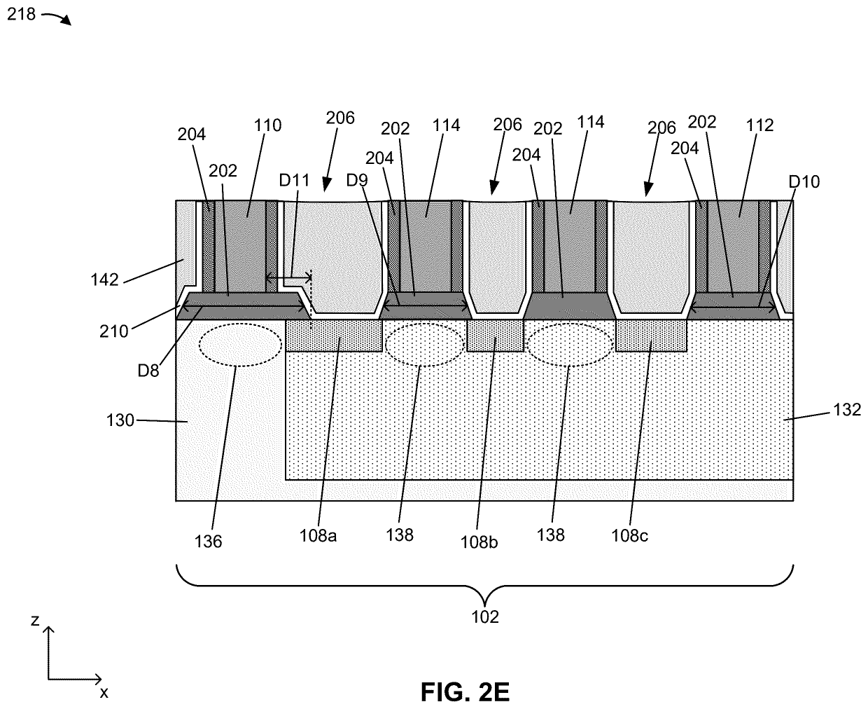

FIGS. 2A-2E are diagrams of example implementations of gate structures included in an ESD protection device 102 described herein. The example implementations illustrated in FIGS. 2A-2E include example implementations of active gate structures 110, dummy gate structures 112, and/or dummy gate structures 114. While each of FIGS. 2A-2E illustrates a different example implementation of gate structures, the example implementations of gate structures 2A-2E may be combined in various combinations for the active gate structures 110, dummy gate structures 112, and/or dummy gate structures 114. For example, an active gate structure 110, a dummy gate structure 112, and a dummy gate structure 114 may each include a different example implementation of gate structure in FIGS. 2A-2E. As another example, two or more dummy gate structures 114 may each include a different example implementation of gate structure in FIGS. 2A-2E.

FIG. 2A illustrates an example implementation 200 of gate structures included in an ESD protection device 102. As shown in FIG. 2A, a gate structure (e.g., an active gate structure 110, a dummy gate structure 112, and/or a dummy gate structure 114) may include a gate dielectric layer 202 on the substrate 104. The gate dielectric layer 202 is included between the substrate 104 and a gate structure. Sidewall spacers 204 are included on the sidewalls of a gate structure. The sidewall spacers 204 may have a rounded or curved outer sidewall that may result from the formation process for the sidewall spacers 204. The gate dielectric layer 202 may include one or more dielectric materials, such as a low dielectric constant (low-k) dielectric material (e.g., silicon oxide (SiOₓ such as SiO₂)), a high dielectric constant (high-k) dielectric material (e.g., hafnium oxide (HfOₓ such as HfO₂)), and/or another suitable gate dielectric material. The sidewall spacers 204 may include one or more dielectric materials such as silicon oxide (SiOₓ), silicon nitride (SiₓN_{y} such as Si₃N₄), silicon oxynitride (SiON), and/or another suitable dielectric material.

As further shown in FIG. 2A, the inclusion of the dummy gate structures 114 may enable a minimal amount of dishing to occur in regions 206 of an ILD layer 142 surrounding the active gate structures 110, the dummy gate structures 112, and the dummy gate structures 114, because of the greater density of gate structures that is achieved compared to the dummy gate structures 114 not being included. In some implementations, the magnitude of dishing (dimension D7 in FIG. 2A—the distance between the top of the gate structures and the lowest part of the regions 206) is less than approximately 0.5 microns as a result of the increased gate density provided by the dummy gate structures 114. However, other values and ranges are within the scope of the present disclosure.

FIG. 2B illustrates an example implementation 208 of gate structures included in an ESD protection device 102. As shown in FIG. 2B, a gate structure (e.g., an active gate structure 110, a dummy gate structure 112, and/or a dummy gate structure 114) may include a gate dielectric layer 202 on the substrate 104 and sidewall spacers 204. In the example implementation 208, the sidewalls spacers 204 have substantially straight inner and outer sidewalls. Moreover, a contact etch stop layer (CESL) 210 is included between the gate structures and the ILD layer 142. The CESL 210 may facilitate etching of recesses through the ILD layer 142 for forming of source/drain contacts 116 and 120 of the ESD protection device 102. The CESL 210 may each include one or more dielectric materials, such as a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silica glass (FSG), and/or carbon doped silicon oxide, among other examples.

FIG. 2C illustrates an example implementation 212 of gate structures included in an ESD protection device 102. As shown in FIG. 2C, the example implementation 212 of gate structures is similar to the example implementation 208 of gate structures in FIG. 2B. However, as illustrated in FIG. 2C, a capping layer 214 is included on the gate structures. The capping layer 214 may include one or more dielectric materials, such as a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silica glass (FSG), and/or carbon doped silicon oxide, among other examples.

FIG. 2D illustrates an example implementation 216 of gate structures included in an ESD protection device 102. As shown in FIG. 2D, the example implementation 216 of gate structures is similar to the example implementation 208 of gate structures in FIG. 2B. However, as illustrated in FIG. 2D, the gate dielectric layers 202 of the gate structures have tapered sidewalls. Thus, a lateral width of the gate dielectric layers 202 is greater at the bottom of the gate dielectric layers 202 than at the top of the gate dielectric layers 202. The tapered sidewalls may result from the parameters and/or the techniques that are used to form the gate dielectric layers 202.

FIG. 2E illustrates an example implementation 218 of gate structures included in an ESD protection device 102. As shown in FIG. 2E, the example implementation 218 of gate structures is similar to the example implementation 216 of gate structures in FIG. 2D. However, as illustrated in FIG. 2E, the lateral width of the gate dielectric layer 202 of the active gate structure 110 (indicated in FIG. 2E as dimension D8) is greater than the lateral width of the gate dielectric layers 202 of the dummy gate structures 114 (indicated in FIG. 2E as dimension D9), and is greater than the lateral width of the gate dielectric layer 202 of the dummy gate structure 112 (indicated in FIG. 2E as dimension D10).

The greater lateral width of the gate dielectric layer 202 of the active gate structure 110 may be achieved as a result of the increased gate density in the ESD protection device 102 provided by the inclusion of the dummy gate structures 114. The increased gate density enables a masking layer, that is used to pattern and etch a dielectric layer to form the gate dielectric layers 202, to be formed to a greater thickness than without the dummy gate structures 114. The greater thickness of the masking layer enables the masking layer to better withstand or resist lateral etching of the masking layer, which enables the masking layer to extend laterally outward past the active gate structure 110 by a greater distance. This enables the gate dielectric layer 202 of the active gate structure 110 to be formed such that the gate dielectric layer 202 extends laterally outward from the active gate structure 110 by an extension distance (indicated in FIG. 2E as dimension D11). This extension distance enables a gate-to-drain spacing parameter (sometimes referred to as a spacing rule (S-rule)) for the ESD protection device 102 to be satisfied, which may enable a low GIDL to be achieved for the ESD protection device 102.

As indicated above, FIGS. 2A-2E are provided as examples. Other examples may differ from what is described with regard to FIGS. 2A-2E.

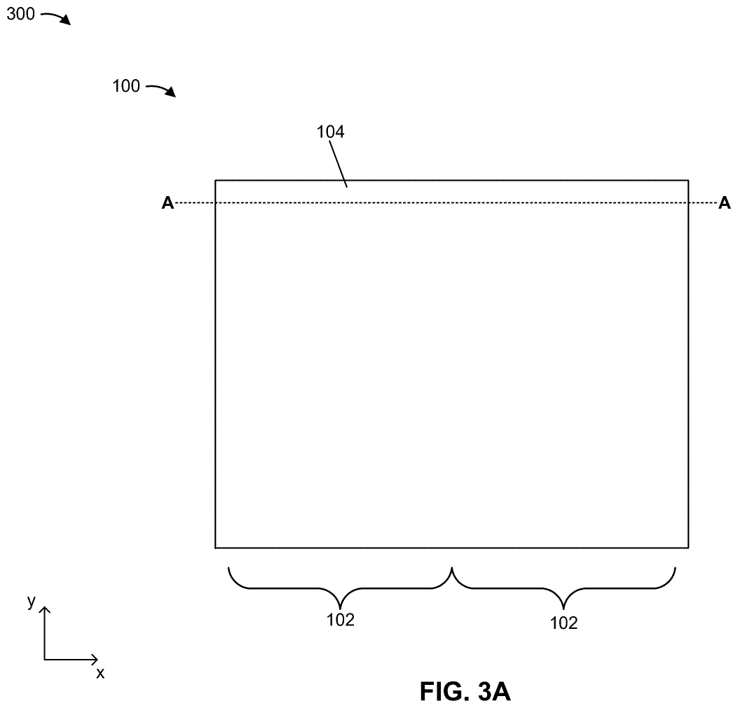

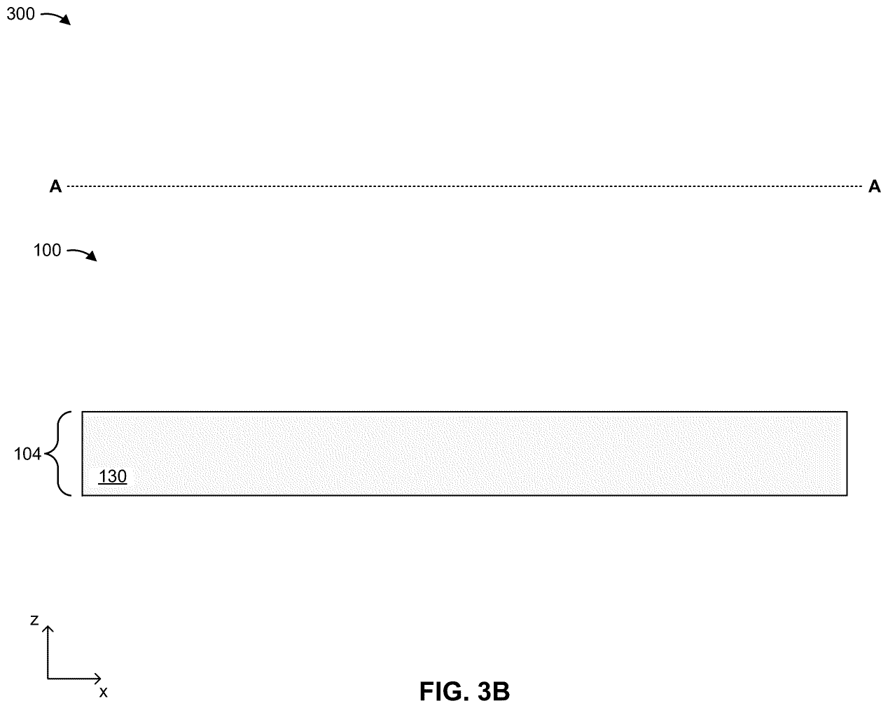

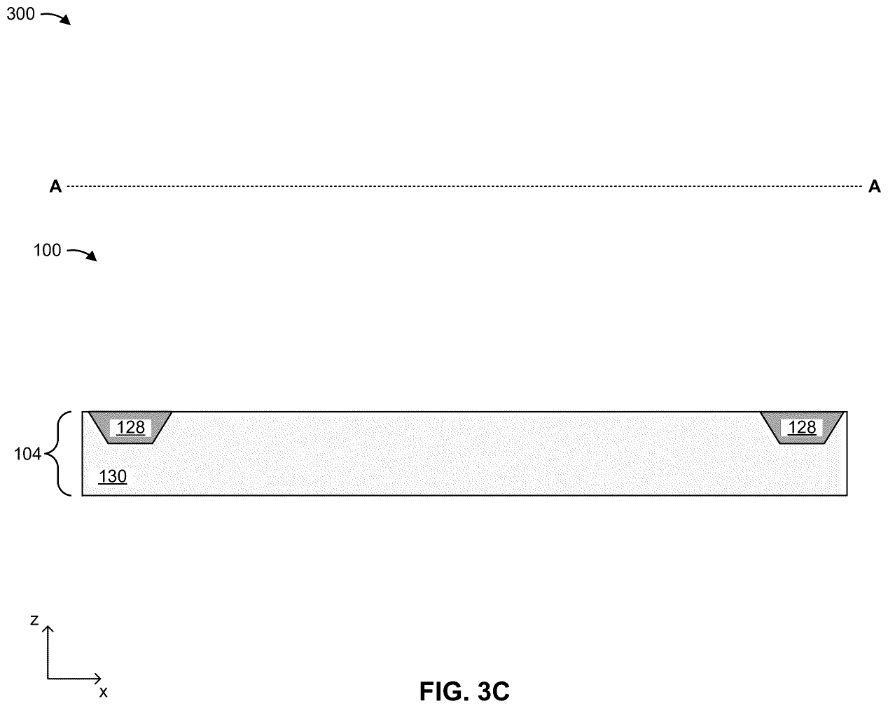

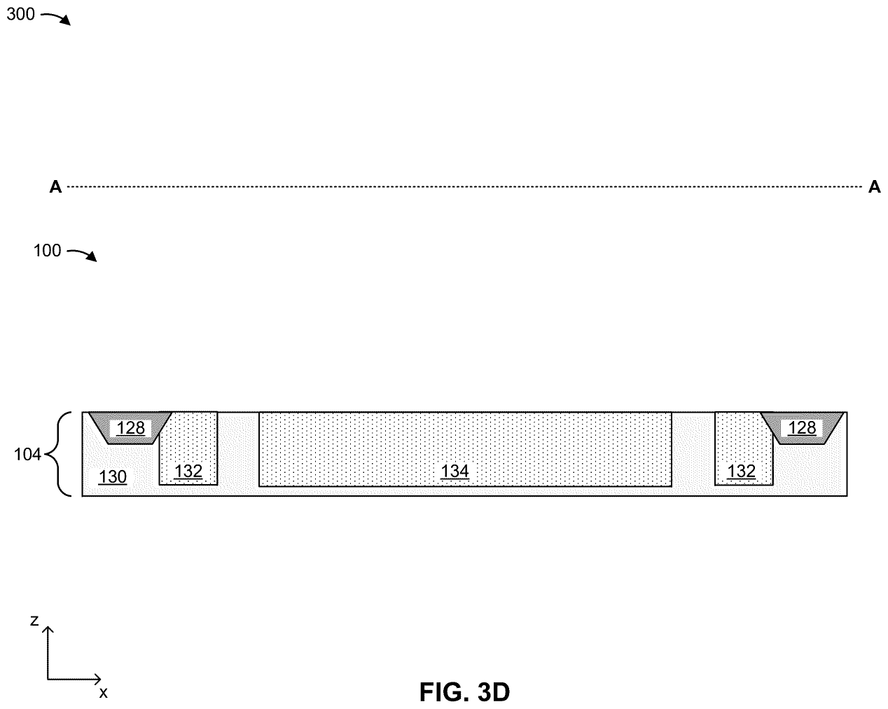

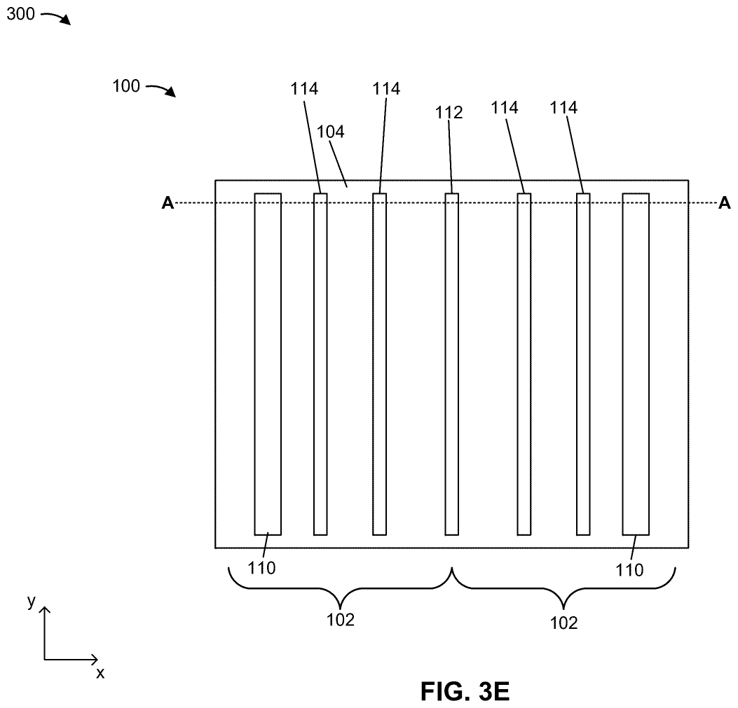

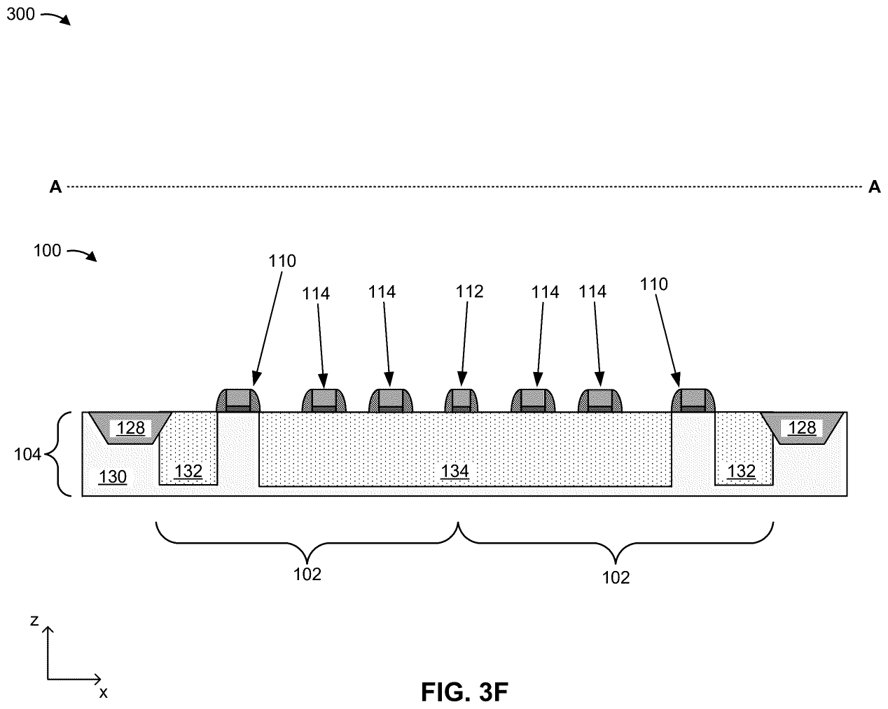

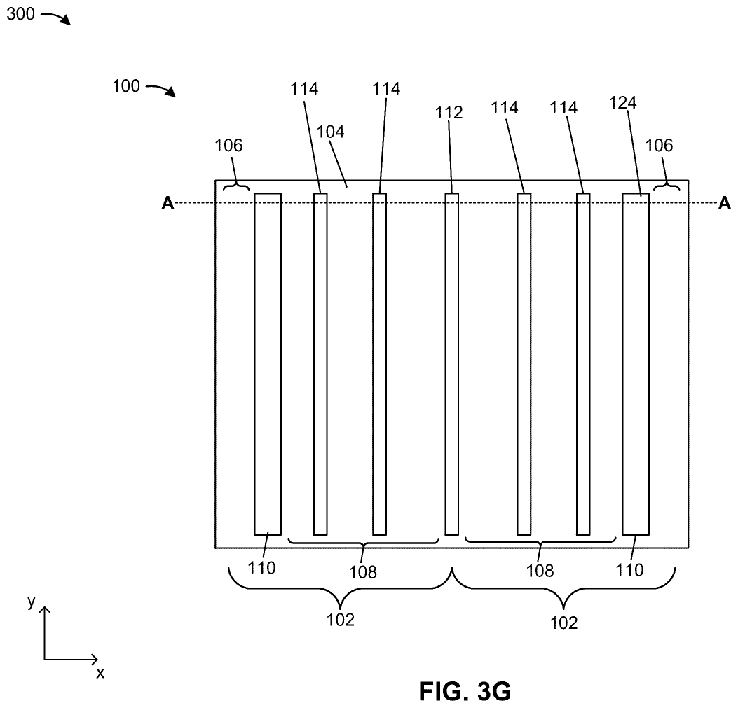

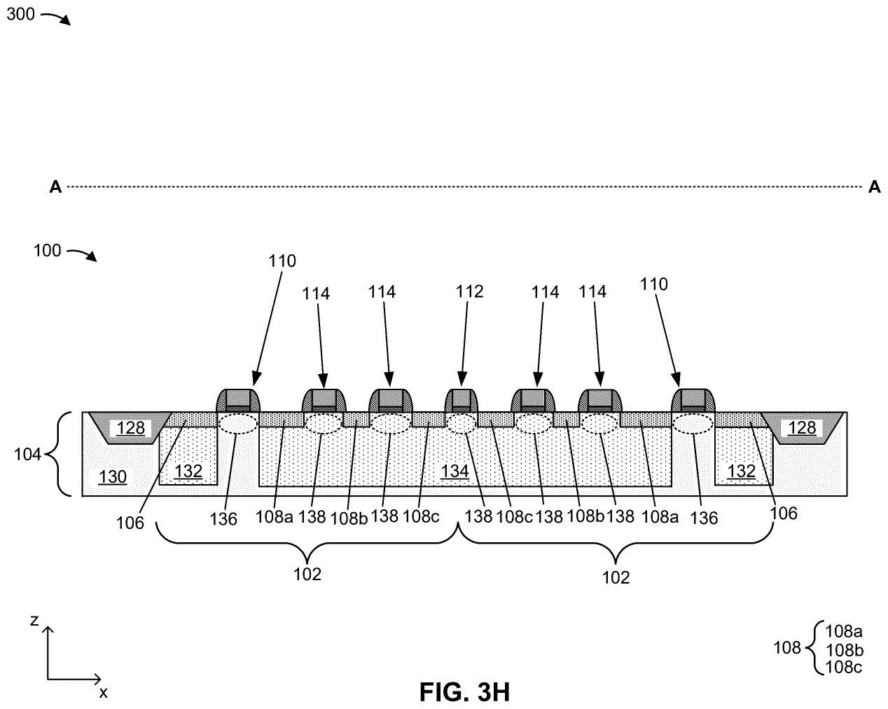

FIGS. 3A-3H are diagrams of an example implementation 300 of ESD protection devices 102 of a semiconductor device (e.g., a semiconductor device 100, 600, 700, 800, an ESD protection device 906, an ESD protection device 908) described herein. In some implementations, one or more of the operations described in connection with FIGS. 3A-3H may be performed using one or more semiconductor processing tools, such as a deposition tool, an exposure tool, a developer tool, an etch tool, an ion implantation tool, and/or a planarization tool, among other examples.

Turning to FIGS. 3A and 3B, the substrate 104 may be provided. The substrate 104 may be provided as a semiconductor wafer, a semiconductor die, and/or another type of semiconductor substrate. In some implementations, the substrate 104 may be a doped substrate, such as a semiconductor substrate that is doped with one or more dopants of a first dopant type (e.g., p-type dopant, n-type dopants) to form the well region 130. In some implementations, the substrate 104 is doped using an implantation tool to form the well region 130. In some implementations, the substrate 104 is doped by diffusion and/or another doping technique.

As shown in FIG. 3C, an STI formation operation is performed to form STI regions 128 in the substrate 104. The STI regions 128 may be formed in the well region 130 and/or in another location in the substrate 104. To form the STI regions 128, recesses may be formed in the substrate 104, and the material of the STI regions 128 may be deposited in the recesses.

In some implementations, a pattern in a photoresist layer is used to etch the substrate 104 to form the recesses. In these implementations, a deposition tool is used to form the photoresist layer on the substrate 104. An exposure tool is used to expose the photoresist layer to a radiation source to pattern the photoresist layer. A developer tool is used to develop and remove portions of the photoresist layer to expose the pattern. An etch tool is used to etch the substrate 104 based on the pattern to form the recesses in the substrate 104. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique). In some implementations, a hard mask layer is used as an alternative technique for etching the substrate 104 based on a pattern.

A deposition tool may be used to deposit the material of the STI regions 128 using a physical vapor deposition (PVD) technique, an atomic layer deposition (ALD) technique, a chemical vapor deposition (CVD) technique, an oxidation operation, and/or another suitable deposition operation. In some implementations, a planarization tool is used to perform a planarization operation such as a chemical mechanical planarization (CMP) operation to planarize the STI regions 128.

As shown in FIG. 3D, one or more well implantation operations may be performed to form the lightly doped implant regions 132 and 134 in the substrate 104. The lightly doped implant regions 132 and 134 may be formed below the surface of the substrate 104. Moreover, the lightly doped implant regions 132 and 134 may be formed in the well region 130. In some implementations, an ion implantation tool is used to perform one or more ion implantation operations to form the lightly doped implant regions 132 and 134 in the substrate 104. In some implementations, an implantation mask is formed on the substrate 104, a pattern is formed in the implantation mask, and the pattern in the implantation mask is used to selectively dope regions of the substrate 104 to form the lightly doped implant regions 132 and 134.

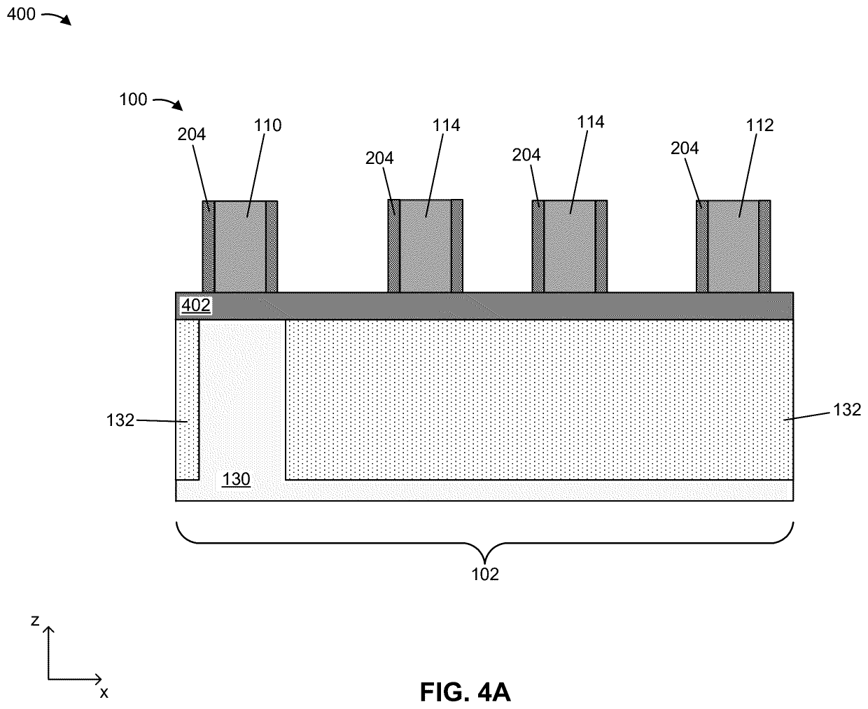

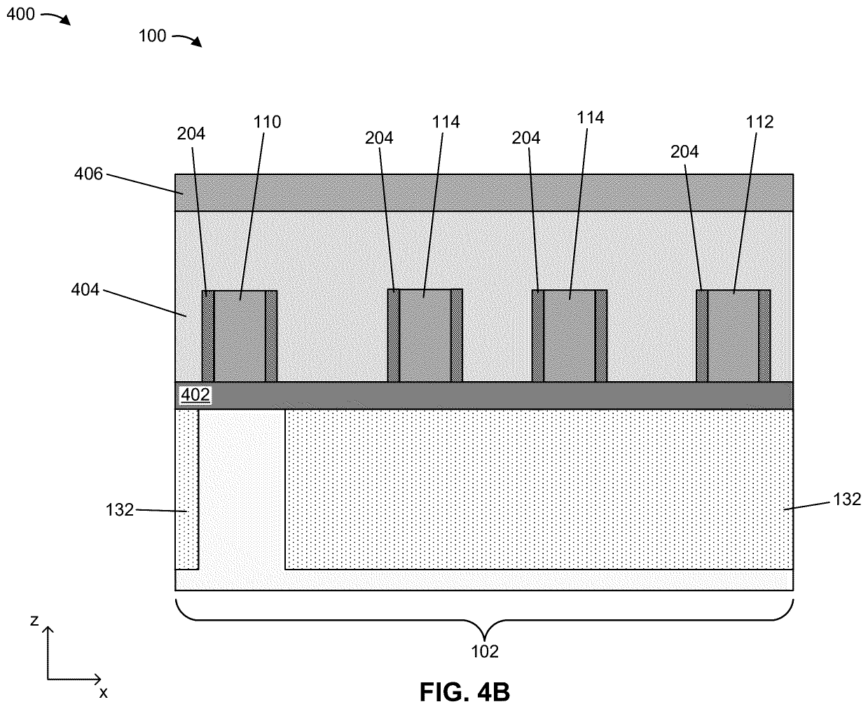

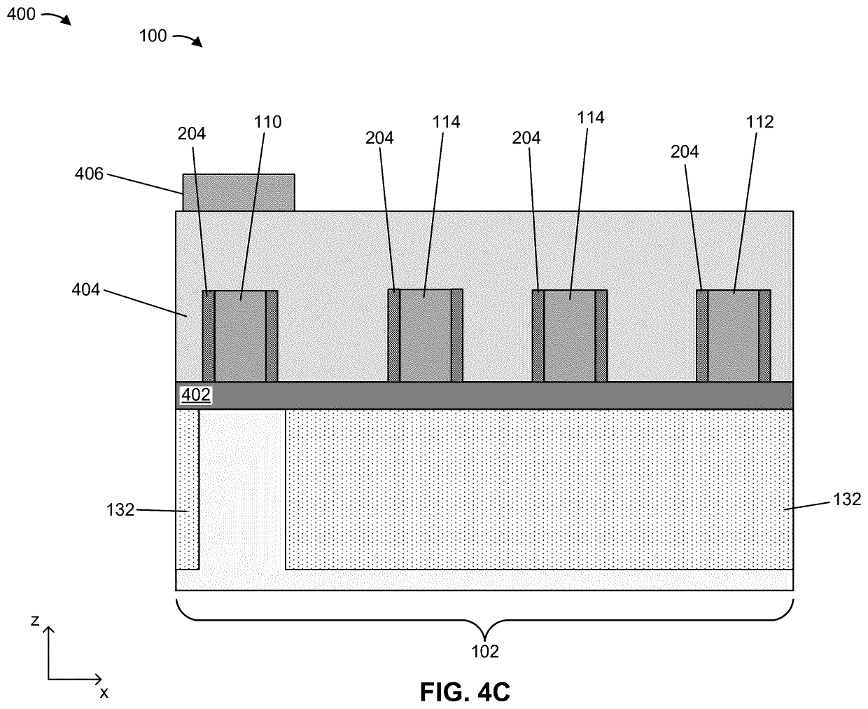

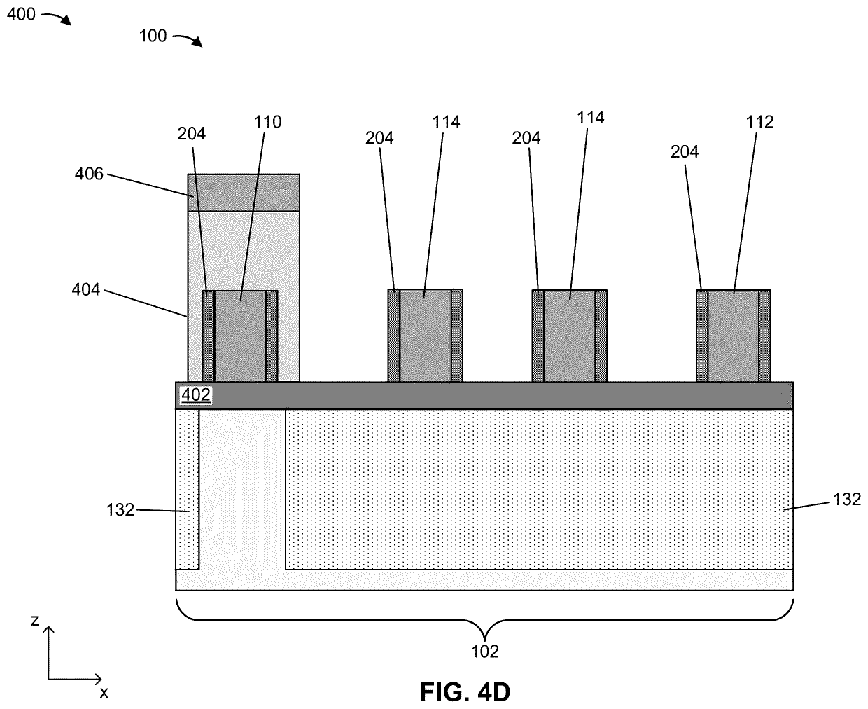

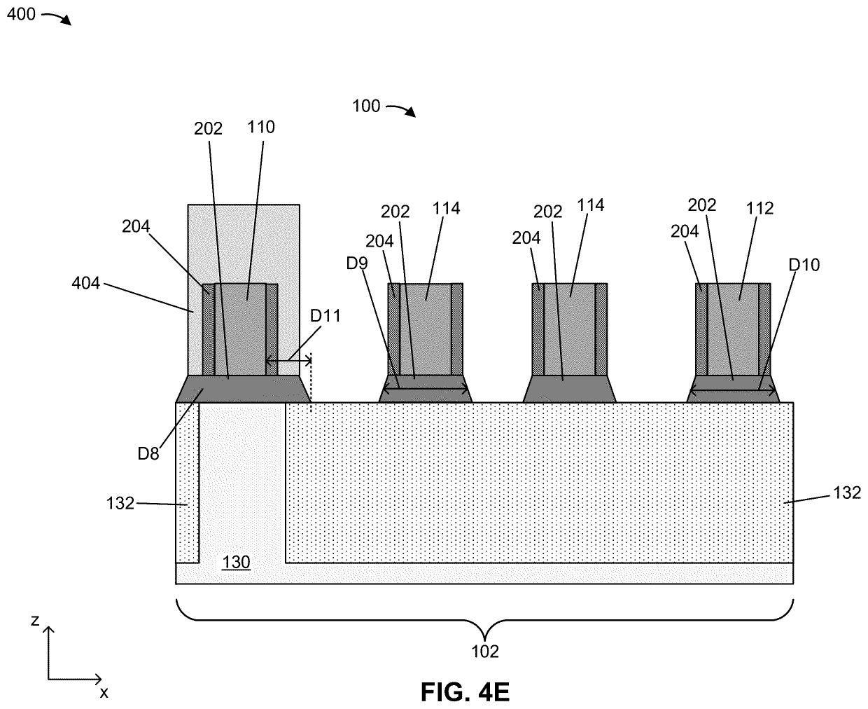

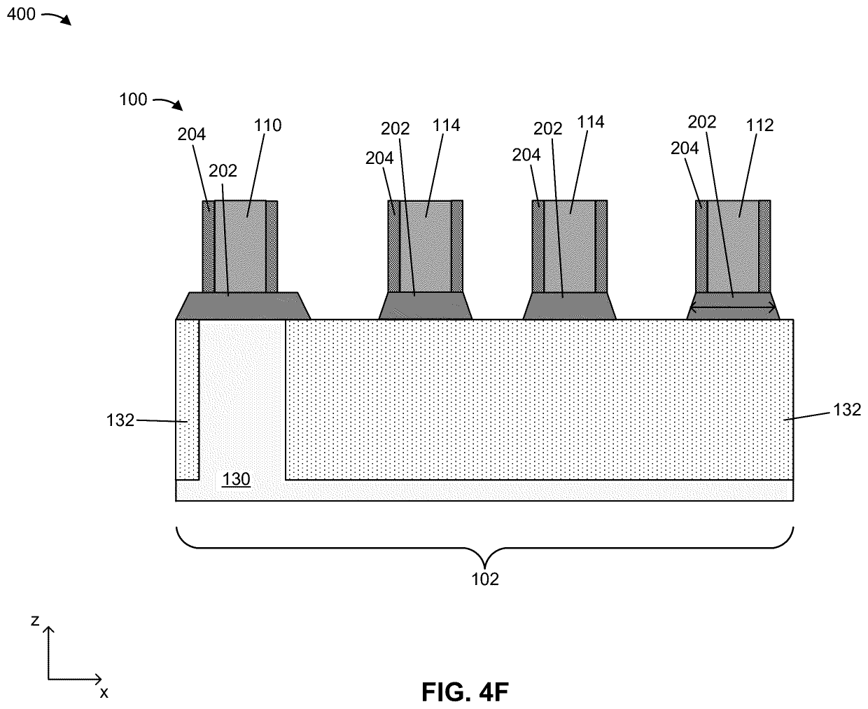

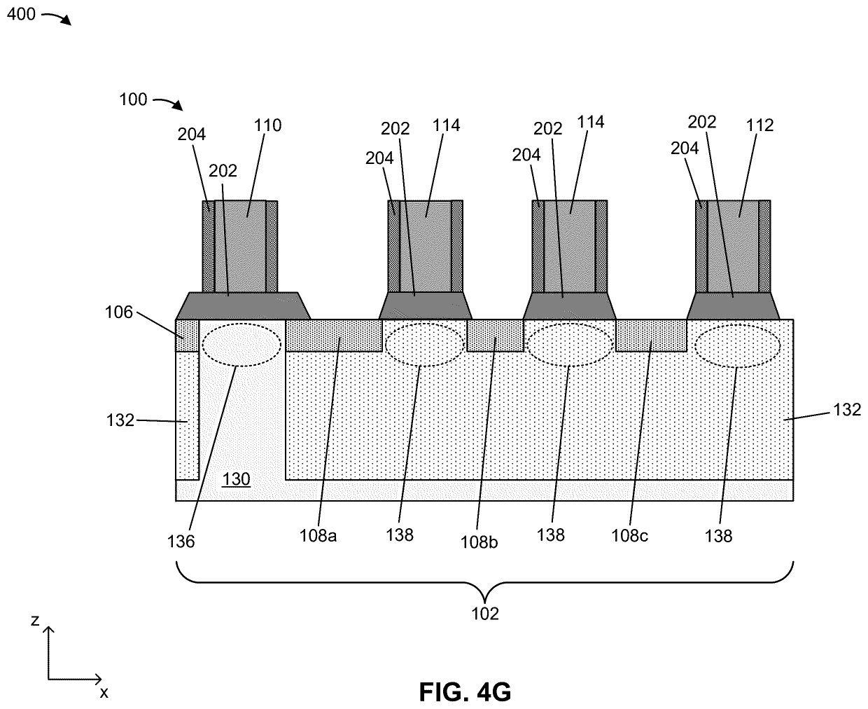

As shown in FIGS. 3E and 3F, the gate structures of the ESD protection devices 102 are formed, including the active gate structures 110, the dummy gate structures 112, and the dummy gate structures 114. The gate structures may be formed on the substrate 104. The dummy gate structures 114 of an ESD protection device 102 may be formed such that the dummy gate structures 114 are located laterally between the active gate structure 110 of the ESD protection device 102 and the dummy gate structure 112 between adjacent ESD protection devices 102. The active gate structure 110 of an ESD protection device 102 may be formed such that the active gate structure 110 is located on a portion of the well region 130 between the lightly doped implant regions 132 and 134. The dummy gate structures 112 and 114 may be formed above the lightly doped implant region 134 of an ESD protection device 102. FIGS. 4A-4G illustrate an example implementation of forming the gate structures of the ESD protection devices 102.

As shown in FIGS. 3G and 3H, the source/drain regions 106 and 108 of the ESD protection devices 102 are formed in the substrate 104. As shown in FIG. 3H, the source/drain regions 106 may each be formed in a lightly doped implant region 132, and the source/drain regions 108 may be formed in a lightly doped implant region 134. As further shown in FIG. 3H, the active gate structures 110, the dummy gate structures 112, and the dummy gate structures 114 function as a self-aligned implant mask that enables regions of the substrate 104 to be selectively doped to form the source/drain regions 106 and the discontinuous implant segments 108a-108c of the source/drain regions 108. This enables undoped regions in the lightly doped implant region 134 to be formed under the dummy gate structures 112 and 114, which provide diffusion regions 138 for which dopants of the discontinuous implant segments 108a-108c of the source/drain regions 108 may diffuse into, to spread out the concentration of dopants in the lightly doped implant region 134.

As indicated above, FIGS. 3A-3H are provided as examples. Other examples may differ from what is described with regard to FIGS. 3A-3H.

FIGS. 4A-4G are diagrams of an example implementation 400 of forming gate structures of an ESD protection device 102 described herein. The ESD protection device 102 may be included in a semiconductor device, such as a semiconductor device 100, 600, 700, 800, an ESD protection device 906, and/or an ESD protection device 908 described herein. In some implementations, one or more of the semiconductor processing operations described in connection with FIGS. 4A-4G may be performed after or as part of one or more operations described in connection with FIGS. 3A-3H. In some implementations, one or more of the operations described in connection with FIGS. 4A-4G may be performed using one or more semiconductor processing tools, such as a deposition tool, an exposure tool, a developer tool, an etch tool, an ion implantation tool, and/or a planarization tool, among other examples.

As shown in FIG. 4A, a dielectric layer 402 may be formed on the substrate after formation of the well region 130 and the lightly doped implant regions 132 and 134. A deposition tool may be used to deposit the dielectric layer 402 using a PVD technique, an ALD technique, a CVD technique, an oxidation technique, and/or another suitable deposition technique. The dielectric layer 402 may be deposited in one or more deposition operations. In some implementations, a planarization tool may be used to perform a planarization operation (e.g., a CMP operation) to planarize the dielectric layer 402 after the dielectric layer 402 is deposited.

As further shown in FIG. 4A, the gate structures of the ESD protection device 102 are formed. For example, the active gate structure 110 of the ESD protection device 102 may be formed above a portion of the well region 130 in the substrate 104 between the lightly doped implant regions 132 and 134. As another example, the dummy gate structures 112 and 114 are formed above the lightly doped implant region 134.

In some implementations, a deposition tool may be used to deposit a gate layer on the dielectric layer 402 using a PVD technique, an ALD technique, a CVD technique, an electroplating technique, and/or another suitable deposition technique. In some implementations, a planarization tool may be used to perform a planarization operation (e.g., a CMP operation) to planarize the gate layer after the gate layer is deposited. In some implementations, a pattern in a photoresist layer is used to etch the gate layer to form the active gate structure 110 and the dummy gate structures 112 and 114. In these implementations, a deposition tool may be used to form the photoresist layer on the gate layer. An exposure tool may be used to expose the photoresist layer to a radiation source to pattern the photoresist layer. A developer tool may be used to develop and remove portions of the photoresist layer to expose the pattern. An etch tool may be used to etch the gate layer based on the pattern to form the active gate structure 110 and the dummy gate structures 112 and 114. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the gate layer based on a pattern.

As further shown in FIG. 4A, the sidewall spacers 204 are formed on the sidewalls of the active gate structure 110, on the sidewalls of the dummy gate structure 112, and on the sidewalls of the dummy gate structure 114. To form the sidewall spacers 204, a spacer layer may be formed on the active gate structure 110 and the dummy gate structures 112 and 114, and on the surface of the substrate 104. In some implementations, a deposition tool may be used to deposit a spacer layer using an ALD technique, a CVD technique, and/or another conformal deposition technique to conformally deposit the spacer layer. The spacer layer may be etched using an anisotropic etch technique such as a plasma-based etch technique to etch the spacer layer in the z-direction. The verticality of the etch technique that is used to etch the spacer layer results in the spacer layer being removed from the tops of the active gate structure 110 and the dummy gate structures 112 and 114, and from the surface of the substrate 104. The spacer layer remains on the sidewalls of the active gate structure 110 and the dummy gate structures 112 and 114 as the sidewall spacers 204. Additionally and/or alternatively, another technique may be used to form the sidewall spacers 204.

As shown in FIG. 4B, a plurality of masking layers may be formed on the ESD protection device 102. For example, a masking layer 404 may be formed on the ESD protection device 102 such that the masking layer 404 covers the active gate structure 110 and the dummy gate structures 112 and 114. Another masking layer 406 may be formed on the masking layer 404. The masking layer 404 may include a hard mask layer that includes one or more dielectric materials such as silicon oxide (SiOₓ), silicon nitride (SiₓN_{y}), silicon oxynitride (SiON), and/or another suitable hard mask material. The masking layer 406 may include a photoresist layer.

A deposition tool may be used to deposit the masking layer 404 using a PVD technique, an ALD technique, a CVD technique, an oxidation technique, and/or another suitable deposition technique. The masking layer 404 may be deposited in one or more deposition operations. In some implementations, a planarization tool may be used to perform a planarization operation (e.g., a CMP operation) to planarize the masking layer 404 after the masking layer 404 is deposited. A deposition tool may be used to deposit the masking layer 406 using a spin-coating technique and/or another suitable deposition technique.

As shown in FIG. 4C, a pattern may be formed in the masking layer 406. To form the pattern, an exposure tool may be used to expose the masking layer 406 to a radiation source based on a pattern in a photomask to pattern the masking layer 406. A developer tool may be used to develop and remove portions of the masking layer 406 to expose the pattern. The pattern results in a portion of the masking layer 406 remaining over the active gate structure 110 of the ESD protection device 102.

As shown in FIG. 4D, an etch tool may be used to etch the masking layer 406 based on the pattern in the masking layer 406. In some implementations, the etch operation includes a dry etch operation (e.g., a plasma-based etch operation, a gas-based etch operation), a wet chemical etch operation, and/or another type of etch operation.

The masking layer 404 is formed to a greater thickness than if the dummy gate structures 114 were not included in the ESD protection device 102. The dummy gate structures 114 increase the density of gate structures in the ESD protection device 102. The increased density of gate structures results in less gap-filling area around the gate structures in the ESD protection device 102, which enables the areas around the gate structures in the ESD protection device 102 to be filled in faster, which enables a greater amount of material of the masking layer 404 to be accumulated above the gate structures of the ESD protection device 102. The greater thickness of the masking layer 404 enables the masking layer 404 to better withstand lateral etching of the portion of the masking layer 404 under the remaining portion of the masking layer 406. In other words, greater thickness of the masking layer 404 results in less undercutting of the portion of the masking layer 404 under the remaining portion of the masking layer 406. This enables the lateral width of the portion of the masking layer 404 under the remaining portion of the masking layer 406 to be retained with minimal reduction in the lateral width.

As shown in FIG. 4E, a photoresist removal tool may be used to remove the remaining portions of the masking layer 406 (e.g., using a chemical stripper, plasma ashing, and/or another technique). As further shown in FIG. 4E, the dielectric layer 402 is etched using the dummy gate structures 112 and 114 as a self-aligned mask in combination with the masking layer 406. The dielectric layer 402 is etched to form the gate dielectric layers 202 of the active gate structure 110 and the dummy gate structures 112 and 114. The use of the masking layer 404 enables the dielectric layer 402 to be etched such that the lateral width of the gate dielectric layer 202 of the active gate structure 110 (dimension D8) is greater than the lateral width of the gate dielectric layers 202 of the dummy gate structures 114 (dimension D9), and is greater than the lateral width of the gate dielectric layer 202 of the dummy gate structure 112 (dimension D10).

The greater lateral width of the gate dielectric layer 202 of the active gate structure 110 may be achieved as a result of the increased gate density in the ESD protection device 102 provided by the inclusion of the dummy gate structures 114. The increased gate density enables a masking layer, that is used to pattern and etch a dielectric layer to form the gate dielectric layers 202, to be formed to a greater thickness than without the dummy gate structures 114. The greater thickness of the masking layer enables the masking layer to better withstand or resist lateral etching of the masking layer, which enables the masking layer to extend laterally out ward past the active gate structure 110 by a greater distance. This enables the gate dielectric layer 202 of the active gate structure 110 to be formed such that the gate dielectric layer 202 extends laterally outward from the active gate structure 110 by an extension distance (indicated in FIG. 2E as dimension D11). This extension distance enables a gate-to-drain spacing parameter (sometimes referred to as a spacing rule (S-rule)) for the ESD protection device 102 to be satisfied, which may enable a low GIDL to be achieved for the ESD protection device 102.

As shown in FIG. 4F, the remaining portions of the masking layer 404 may be removed after etching the dielectric layer 402 to form the gate dielectric layers 202. In some implementations, the remaining portions of the masking layer 404 are removed using a plasma ashing technique. In some implementations, the remaining portions of the masking layer 404 are removed using a wet chemical etch technique. In some implementations, the remaining portions of the masking layer 404 are removed using another suitable technique.

As shown in FIG. 4G, the source/drain regions 106 and 108 of the ESD protection devices 102 are formed in the substrate 104. The active gate structures 110, the dummy gate structure 112, and the dummy gate structures 114 function as a self-aligned implant mask that enables regions of the substrate 104 to be selectively doped to form the source/drain region 106 and the discontinuous implant segments 108a-108c of the source/drain region 108. This enables undoped regions in the lightly doped implant region 134 to be formed under the dummy gate structures 112 and 114, which provide diffusion regions 138 for which dopants of the discontinuous implant segments 108a-108c of the source/drain region 108 may diffuse into, to spread out the concentration of dopants in the lightly doped implant region 134.

As indicated above, FIGS. 4A-4G are provided as examples. Other examples may differ from what is described with regard to FIGS. 4A-4G.

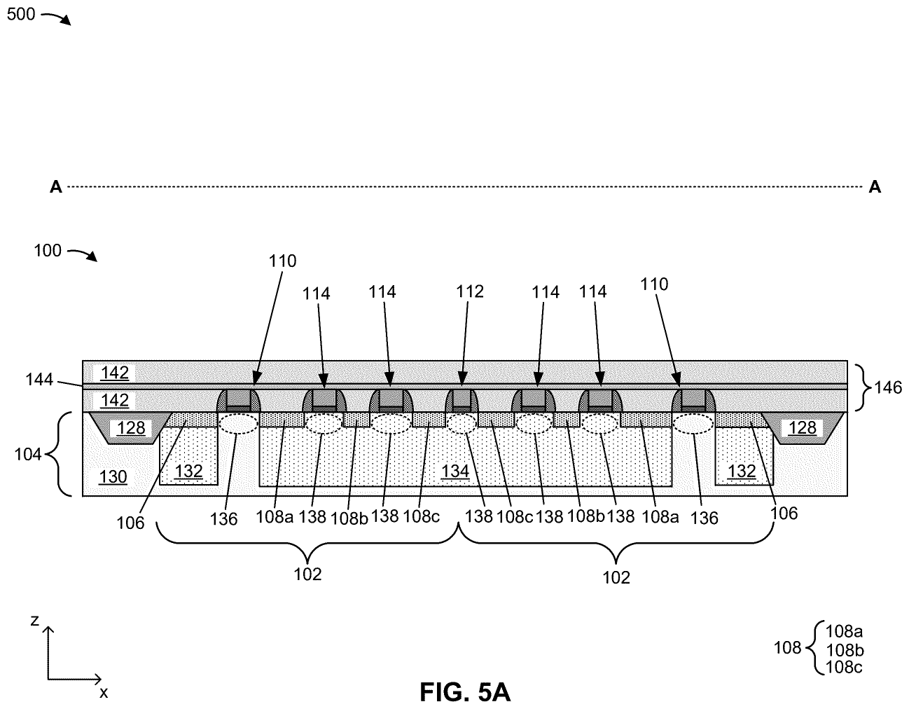

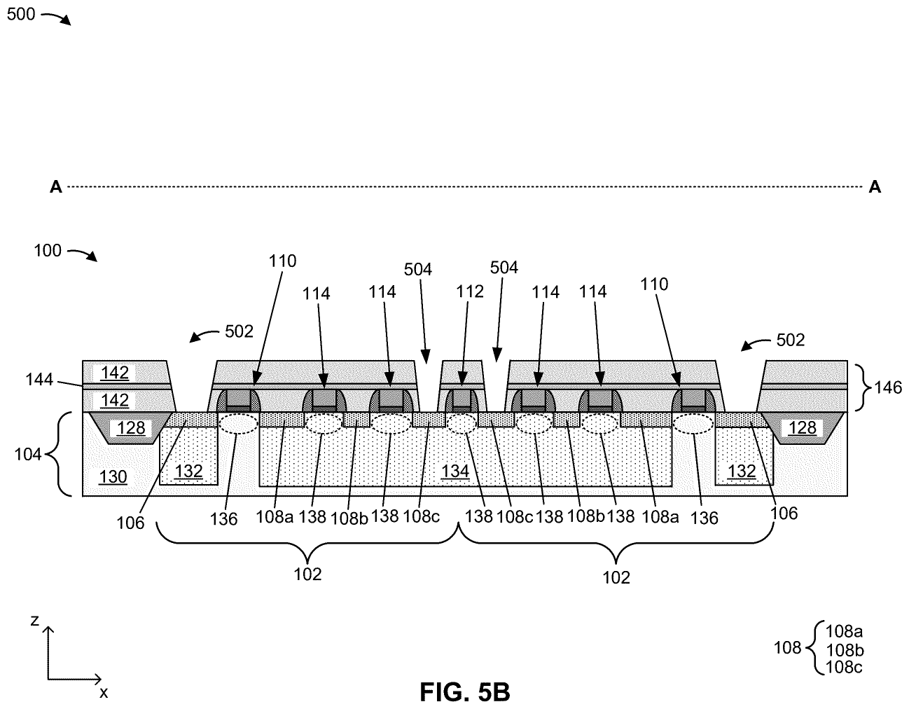

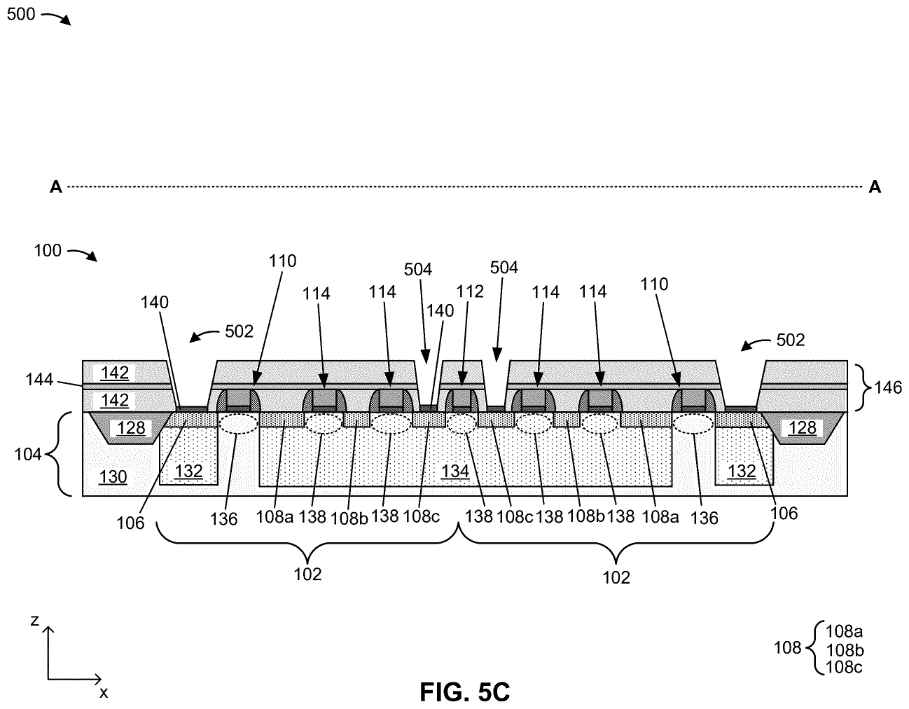

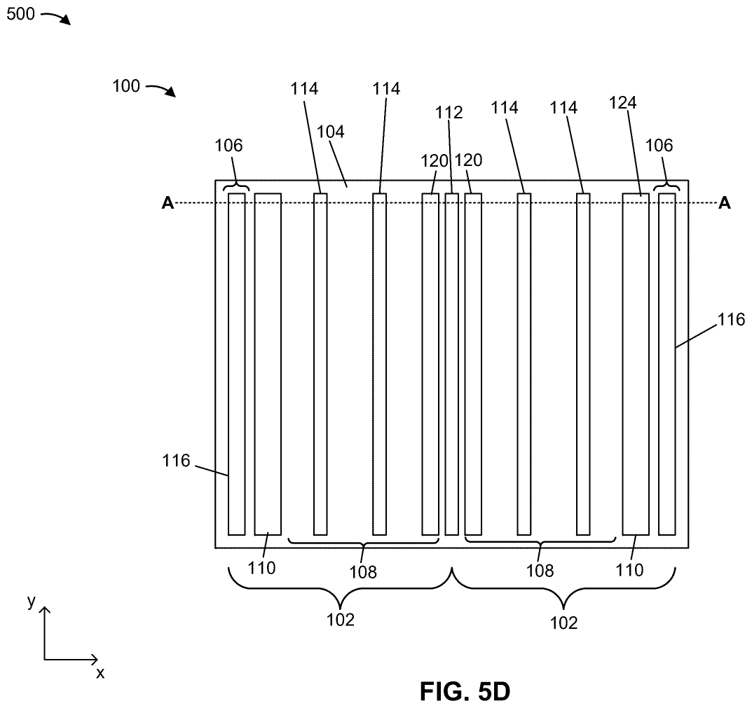

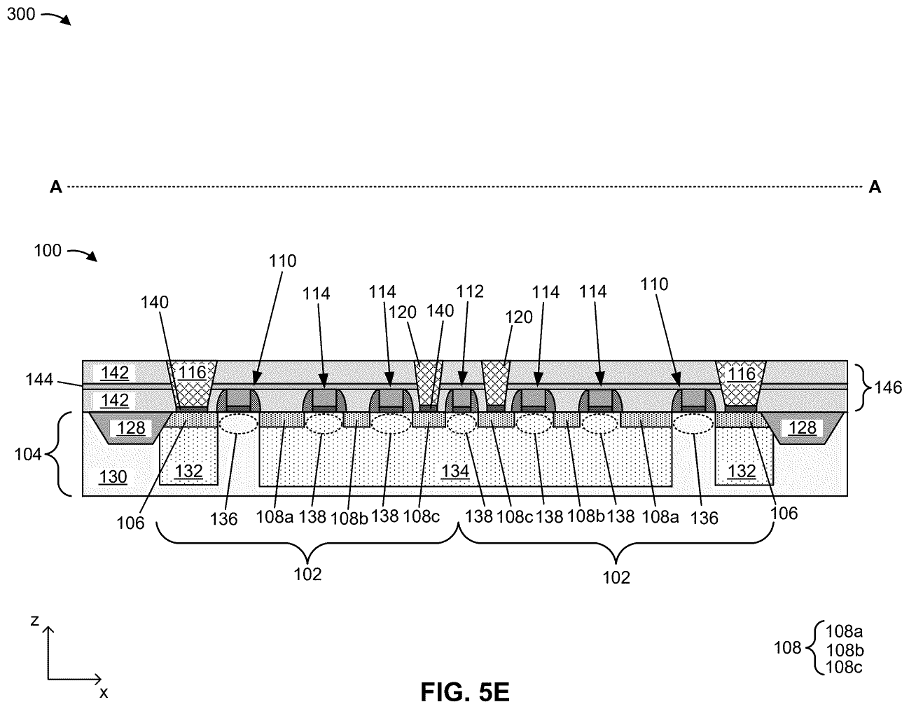

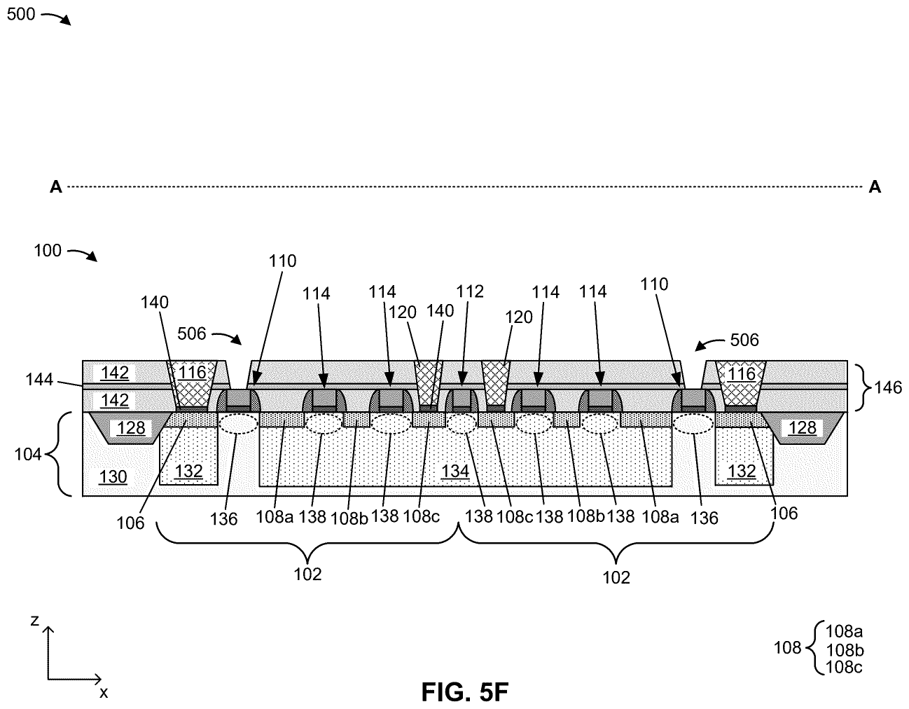

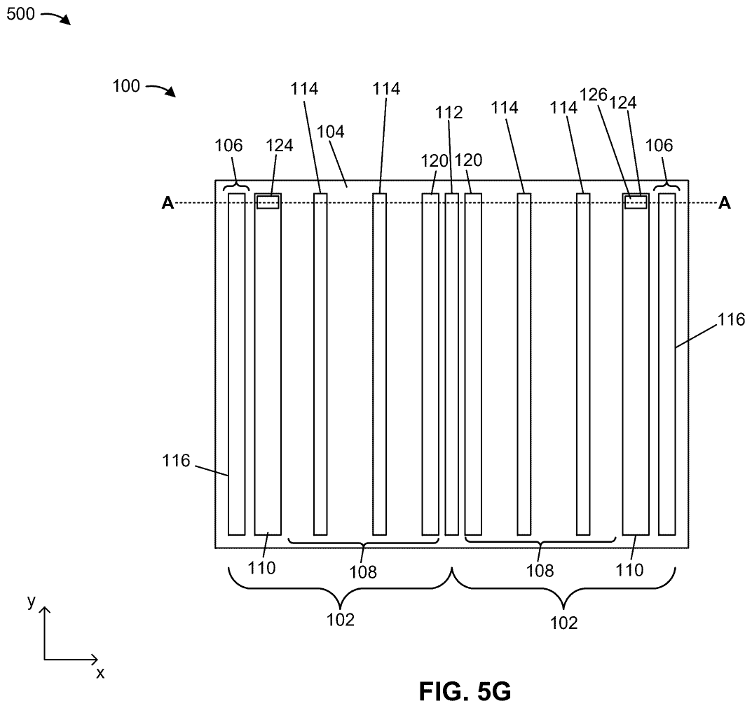

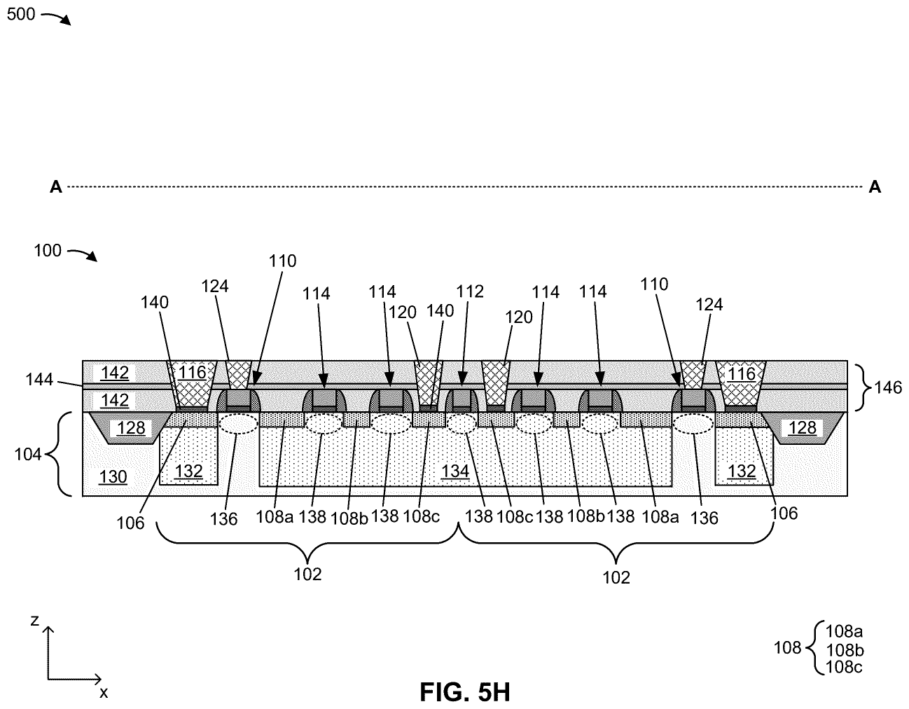

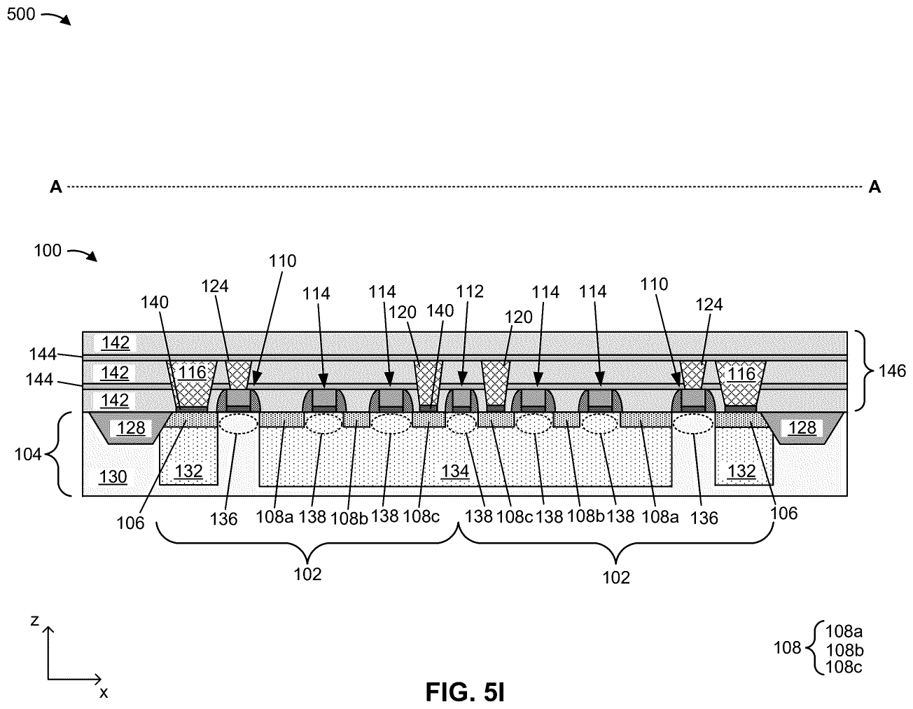

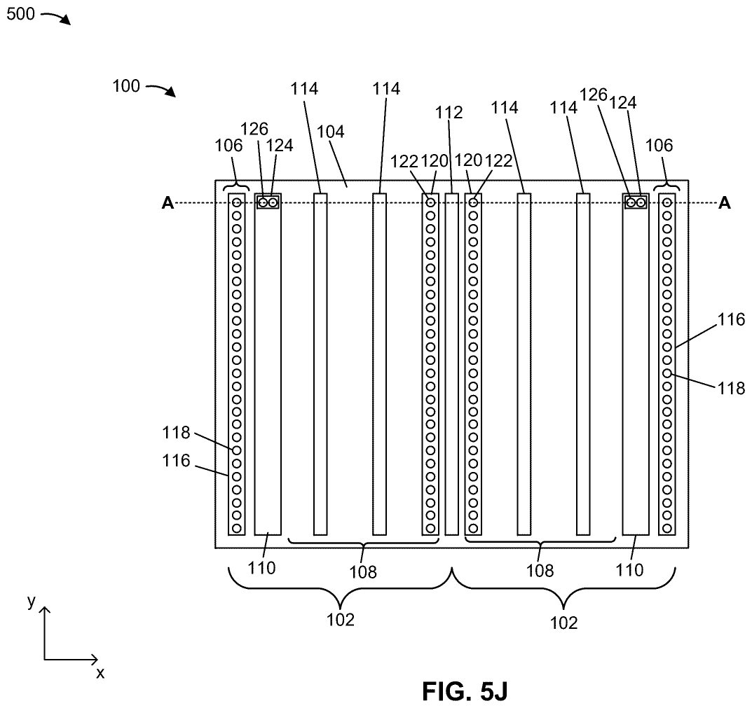

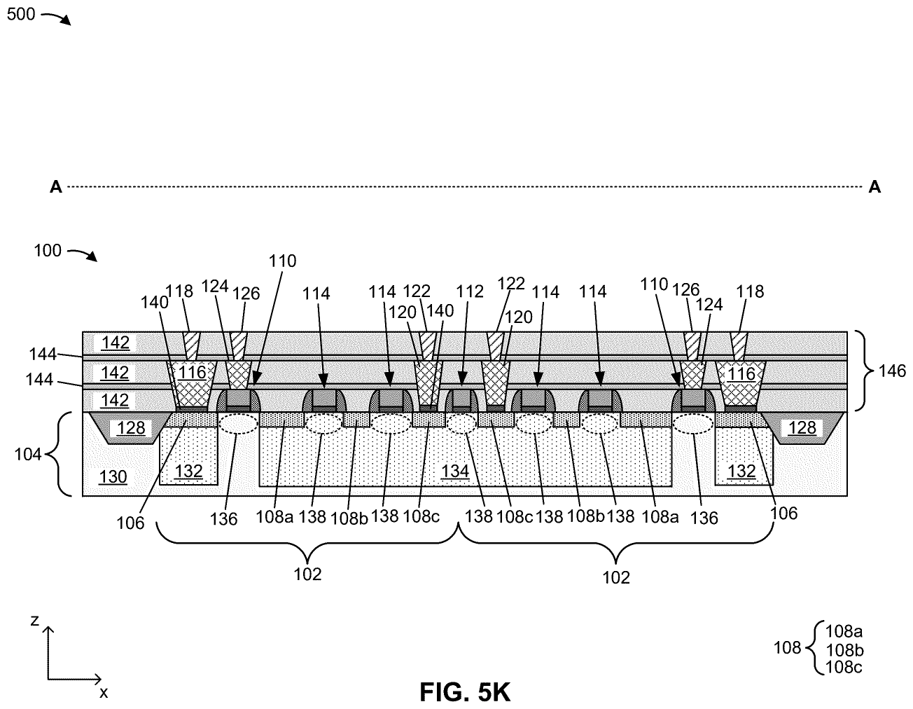

FIGS. 5A-5K are diagrams of an example implementation 500 of forming an interconnect layer 146 of a semiconductor device (e.g., a semiconductor device 100, 600, 700, 800, an ESD protection device 906, an ESD protection device 908) described herein. In some implementations, one or more of the semiconductor processing operations described in connection with FIGS. 5A-5K may be performed after one or more operations described in connection with FIGS. 3A-3H and/or 4A-4G. In some implementations, one or more of the operations described in connection with FIGS. 5A-5K may be performed using one or more semiconductor processing tools, such as a deposition tool, an exposure tool, a developer tool, an etch tool, and/or a planarization tool, among other examples.

As shown in FIG. 5A, one or more ILD layers 142 and one or more ESLs 144 of the interconnect layer 146 may be formed above the substrate 104 and over the gate structures (e.g., the active gate structures 110, the dummy gate structures 112 and 114) of the ESD protection devices 102. The ILD layer(s) 142 and the ESL(s) 144 may be deposited in an alternating manner in the z-direction in the interconnect layer 146.

A deposition tool may be used to deposit an ILD layer 142 using a PVD technique, an ALD technique, a CVD technique, an oxidation technique, and/or another suitable deposition technique. An ILD layer 142 may be deposited in one or more deposition operations. In some implementations, a planarization tool may be used to perform a planarization operation (e.g., a CMP operation) to planarize an ILD layer 142 after the ILD layer 142 is deposited.

A deposition tool may be used to deposit an ESL 144 using a PVD technique, an ALD technique, a CVD technique, an oxidation technique, and/or another suitable deposition technique. An ESL 144 may be deposited in one or more deposition operations. In some implementations, a planarization tool may be used to perform a planarization operation (e.g., a CMP operation) to planarize an ESL 144 after the ESL 144 is deposited.

As shown in FIG. 5B, recesses 502 and 504 may be formed through the ILD layer(s) 142 and the ESL(s) 144. The recesses 502 may be formed over the source/drain regions 106 of the ESD protection devices 102, and the recesses 504 may be formed over the source/drain regions 108 of the ESD protection devices 102. In particular, a recess 504 may be formed over an implant segment 108c of a source/drain region 108 that is located furthest away from the active gate structure 110 of an ESD protection device 102. Alternatively, the recesses 504 may be formed over another implant segment of the source/drain regions 108 of the ESD protection devices 102.

In some implementations, a pattern in a photoresist layer is used to etch the ILD layer(s) 142 and the ESL(s) 144 to form the recesses 502 and 504. In these implementations, a deposition tool may be used to form the photoresist layer on the topmost ILD layer 142. An exposure tool may be used to expose the photoresist layer to a radiation source to pattern the photoresist layer. A developer tool may be used to develop and remove portions of the photoresist layer to expose the pattern. An etch tool may be used to etch the ILD layer(s) 142 and the ESL(s) 144 based on the pattern to form the recesses 502 and 504. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recesses 502 and 504 based on a pattern.

As shown in FIG. 5C, a salicide process (e.g., a self-aligned silicide process) may be performed to form silicide layers 140 on the tops of the source/drain regions 106 at the bottoms of the recesses 502, and to form silicide layers 140 on the tops of the source/drain regions 108 (e.g., the tops of the implant segments 108c) at the bottoms of the recesses 504. The salicide process may include depositing a metal layer such as titanium (Ti) on the semiconductor device 100, including in the recesses 502 and 504. The metal layer is then annealed. The salicide process may be self-aligned in that the annealing of the metal layer causes the metal layer to selectively react with the semiconductor material (e.g., silicon (Si)) of the source/drain regions 106 and 108, thereby forming the silicide layers 140 at the bottoms of the recesses 502 and 504. Unreacted material from the metal layer on other parts of the semiconductor device 100 may be subsequently removed (e.g., by etching and/or another suitable technique).

As shown in FIG. 5D, the source/drain contacts 116 are formed on the source/drain regions 106, and the source/drain contacts 120 are formed on the source/drain regions 108. A source/drain contact 116 of an ESD protection device 102 may be formed adjacent to a first side of an active gate structure 110 of the ESD protection device 102, and a source/drain contact 120 of the ESD protection device 102 may be formed on an opposing second side of the active gate structure 110 such that the dummy gate structures 114 of the ESD protection device 102 are located between the active gate structure 110 and the source/drain contact 120.

As shown in FIG. 5E, the source/drain contacts 116 are formed on the silicide layers 140 in the recesses 502 such that the source/drain contacts 116 are located above the source/drain regions 106. The source/drain contacts 120 are formed on the silicide layers 140 in the recesses 504 such that the source/drain contacts 120 are located above an implant segment (e.g., the implant segments 108c) of the source/drain regions 108.

A deposition tool may be used to deposit the source/drain contacts 116 and 120 using a CVD technique, a PVD technique, an ALD technique, an electroplating technique, and/or another suitable deposition technique. The source/drain contacts 116 and 120 may be deposited in one or more deposition operations. In some implementations, a seed layer is first deposited, and a source/drain contact 116 or 120 is deposited on the seed layer. In some implementations, a liner (e.g., an adhesion liner, a barrier liner) is first deposited, and a source/drain contact 116 or 120 is deposited on the liner. In some implementations, a planarization tool is used to perform a planarization operation (e.g., a CMP operation) to planarize the source/drain contacts 116 and 120 after the source/drain contacts 116 and 120 are deposited.

As shown in FIG. 5F, recesses 506 may be formed through the ILD layer(s) 142 and the ESL(s) 144. The recesses 506 may be formed over the active gate structures 110 of the ESD protection devices 102. In some implementations, a pattern in a photoresist layer is used to etch the ILD layer(s) 142 and the ESL(s) 144 to form the recesses 506. In these implementations, a deposition tool may be used to form the photoresist layer on the topmost ILD layer 142. An exposure tool may be used to expose the photoresist layer to a radiation source to pattern the photoresist layer. A developer tool may be used to develop and remove portions of the photoresist layer to expose the pattern. An etch tool may be used to etch the ILD layer(s) 142 and the ESL(s) 144 based on the pattern to form the recesses 506. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recesses 506 based on a pattern.

As shown in FIG. 5G, gate contacts 124 may be formed on the active gate structures 110 of the ESD protection devices 102. In some implementations, the gate contacts 124 are formed at ends of the active gate structures 110. In some implementations, the gate contacts 124 are formed at another location on the active gate structures 110.

As shown in FIG. 5H, the gate contacts 124 are formed in the recesses 506 such that the gate contacts 124 land on the active gate structures 110 of the ESD protection devices 102. A deposition tool may be used to deposit the gate contacts 124 using a CVD technique, a PVD technique, an ALD technique, an electroplating technique, and/or another suitable deposition technique. The gate contacts 124 may be deposited in one or more deposition operations. In some implementations, a seed layer is first deposited, and a gate contact 124 is deposited on the seed layer. In some implementations, a liner (e.g., an adhesion liner, a barrier liner) is first deposited, and a gate contact 124 are deposited on the liner. In some implementations, a planarization tool is used to perform a planarization operation (e.g., a CMP operation) to planarize the gate contacts 124 after the gate contacts 124 are deposited.

As shown in FIG. 5I, one or more additional ILD layers 142 and one or more additional ESLs 144 of the interconnect layer 146 may be formed. The additional ILD layer(s) 142 and the additional ESL(s) 144 may be deposited in an alternating manner in the z-direction in the interconnect layer 146.

A deposition tool may be used to deposit an ILD layer 142 using a PVD technique, an ALD technique, a CVD technique, an oxidation technique, and/or another suitable deposition technique. An ILD layer 142 may be deposited in one or more deposition operations. In some implementations, a planarization tool may be used to perform a planarization operation (e.g., a CMP operation) to planarize an ILD layer 142 after the ILD layer 142 is deposited.

A deposition tool may be used to deposit an ESL 144 using a PVD technique, an ALD technique, a CVD technique, an oxidation technique, and/or another suitable deposition technique. An ESL 144 may be deposited in one or more deposition operations. In some implementations, a planarization tool may be used to perform a planarization operation (e.g., a CMP operation) to planarize an ESL 144 after the ESL 144 is deposited.

As shown in FIGS. 5J and 5K, source/drain interconnects 118 may be formed on the source/drain contacts 116, source/drain interconnects 122 may be formed on the source/drain contacts 120, and gate interconnects 126 may be formed on the gate contacts 124.

Recesses may be formed through the additional ILD layer(s) 142 and the additional ESL(s) 144 for the source/drain interconnects 118, the source/drain interconnects 122, and the gate interconnects 126. The recesses may be formed over the source/drain contacts 116, over the source/drain contacts 120, and over the gate contacts 124. In some implementations, a pattern in a photoresist layer is used to etch the ILD layer(s) 142 and the ESL(s) 144 to form the recesses. In these implementations, a deposition tool may be used to form the photoresist layer on the topmost ILD layer 142. An exposure tool may be used to expose the photoresist layer to a radiation source to pattern the photoresist layer. A developer tool may be used to develop and remove portions of the photoresist layer to expose the pattern. An etch tool may be used to etch the ILD layer(s) 142 and the ESL(s) 144 based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recesses based on a pattern.

The source/drain interconnects 118 may be formed in recesses such that the source/drain interconnects 118 land on the source/drain contacts 116. The source/drain interconnects 122 may be formed in recesses such that the source/drain interconnects 122 land on the source/drain contacts 120. The gate interconnects 126 may be formed in recesses such that the gate interconnects 126 land on the gate contacts 124.

A deposition tool may be used to deposit the source/drain interconnects 118, the source/drain interconnects 122, and the gate interconnects 126 using a CVD technique, a PVD technique, an ALD technique, an electroplating technique, and/or another suitable deposition technique. The source/drain interconnects 118, the source/drain interconnects 122, and the gate interconnects 126 may be deposited in one or more deposition operations. In some implementations, a seed layer is first deposited, and a source/drain interconnect 118, a source/drain interconnect 122, or a gate interconnect 126 is deposited on the seed layer. In some implementations, a liner (e.g., an adhesion liner, a barrier liner) is first deposited, and a source/drain interconnect 118, a source/drain interconnect 122, or a gate interconnect 126 is deposited on the liner. In some implementations, a planarization tool is used to perform a planarization operation (e.g., a CMP operation) to planarize the source/drain interconnects 118, the source/drain interconnects 122, and the gate interconnects 126 after the source/drain interconnects 118, the source/drain interconnects 122, and the gate interconnects 126 are deposited.

As indicated above, FIGS. 5A-5K are provided as examples. Other examples may differ from what is described with regard to FIGS. 5A-5K.

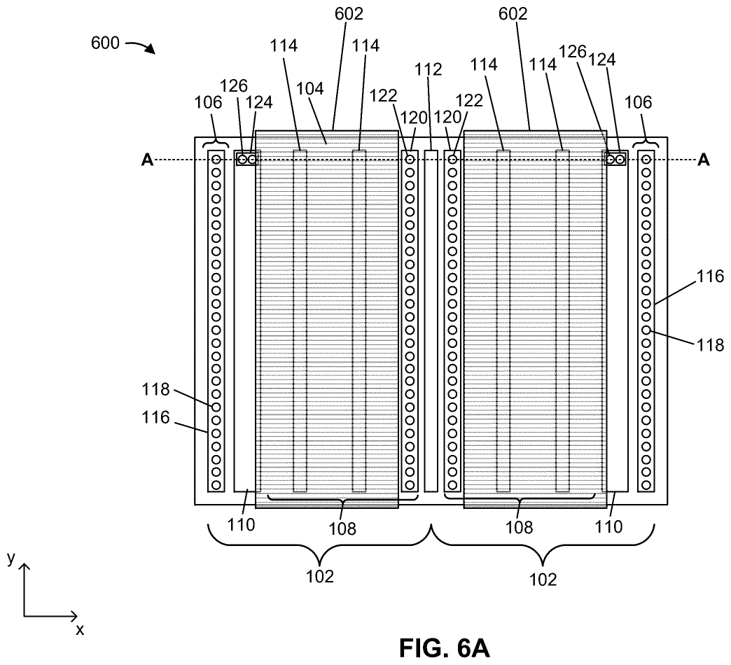

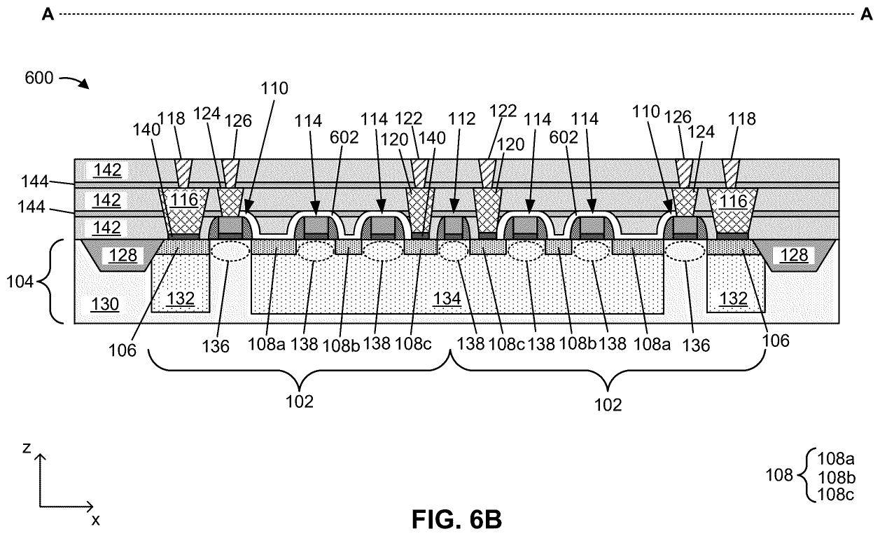

FIGS. 6A and 6B are diagrams of an example semiconductor device 600 described herein. FIG. 6A illustrates a top view of the semiconductor device 600. FIG. 6B illustrates a cross-section view of the semiconductor device 600 along the line A-A in FIG. 6A. As shown in FIGS. 6A and 6B, the semiconductor device 600 includes a similar combination and arrangement of layers and/or structures as the semiconductor device 100 illustrated and described in connection with FIGS. 1A-IC. However, as shown in FIGS. 6A and 6B, the ESD protection devices 102 of the semiconductor device 600 further includes a resist protective oxide (RPO) layer 602 over the dummy gate structures 114 and over a side of the active gate structure 110 facing the source/drain region 108. The RPO layer 602 may include an oxide material such as a silicon oxide (SiOₓ such as SiO₂) and/or another dielectric oxide material.

The RPO layer 602 may be included in an ESD protection device 102 for reduced surface field (RESURF) tuning. The RPO layer 602 reduces the electric field at the surface of the substrate 104 between the active gate structure and the source/drain contact 120, which enables a lower peak electric field strength to be achieved than without the RPO layer 602. The lower peak electric field strength enables the ESD protection devices 102 to handle higher voltages (e.g., stronger ESD events) without experiencing breakdown. Alternatively, the RPO layers 602 may be omitted, as in the semiconductor device 100, to achieve higher on current (Iₒₙ) for the ESD protection devices 102.

The RPO layer 602 may be formed after formation of the source/drain regions 106 and 108, as described in connection FIGS. 3H and FIGS. 4A-4G. For example, the RPO layer 602 may be deposited over the semiconductor device 600, including over the source/drain regions 106 and 108, over the active gate structures 110, over the dummy gate structures 112, and over the dummy gate structures 114. A patterned masking layer may be formed on the RPO layer 602 and used to etch the RPO layer 602 to remove portions of the RPO layer 602. The remaining portions of the RPO layer 602 may be included over the dummy gate structures 114 and over a side of the active gate structure 110 facing the source/drain region 108.

As indicated above, FIGS. 6A and 6B are provided as examples. Other examples may differ from what is described with regard to FIGS. 6A and 6B.

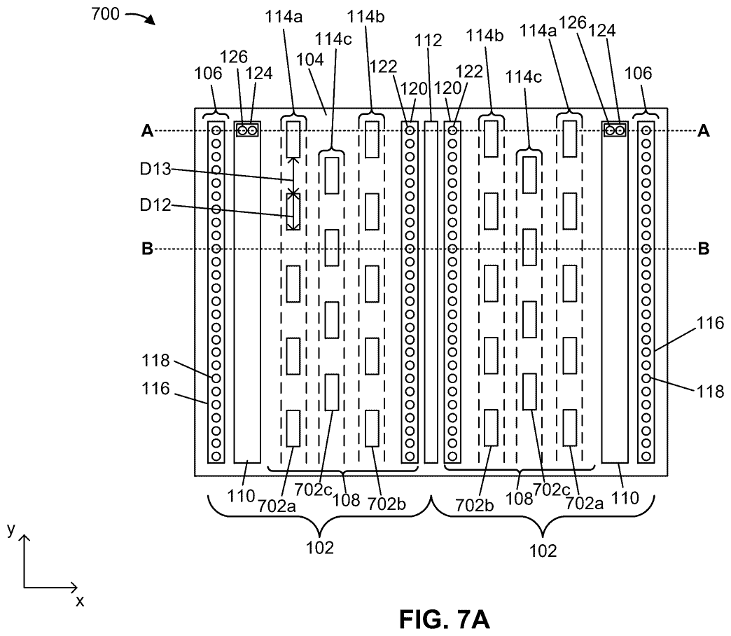

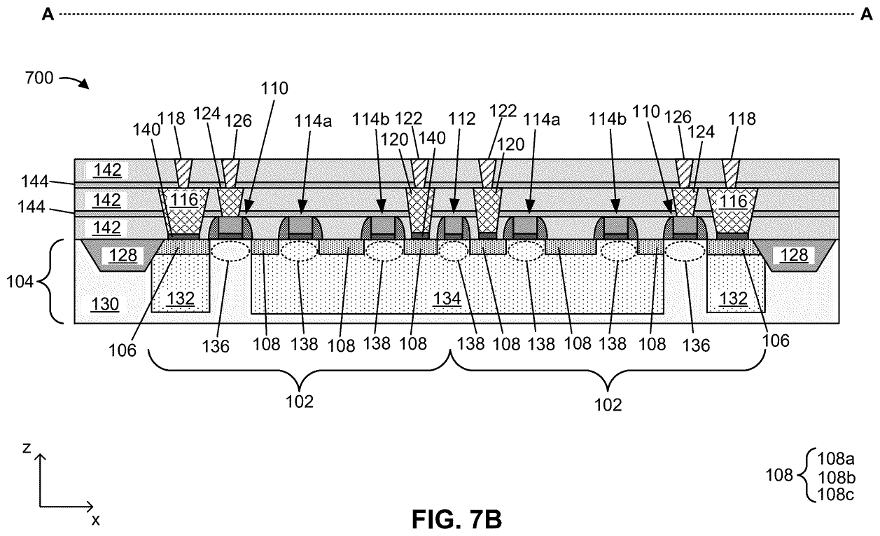

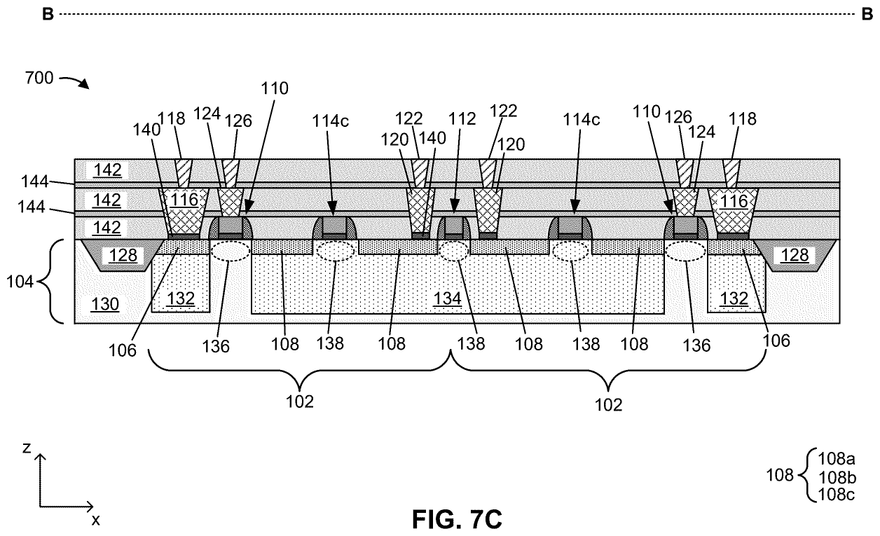

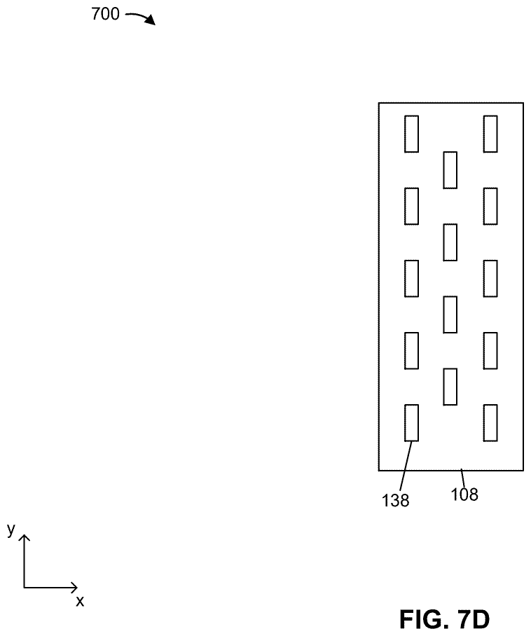

FIGS. 7A-7D are diagrams of an example semiconductor device 700 described herein. FIG. 7A illustrates a top view of the semiconductor device 700. FIG. 7B illustrates a cross-section view of the semiconductor device 700 along the line A-A in FIG. 7A. FIG. 7D illustrates a cross-section view of the semiconductor device 800 along the line B-B in FIG. 7A. As shown in FIGS. 7A-7D, the semiconductor device 700 includes a similar combination and arrangement of layers and/or structures as the semiconductor device 100 illustrated and described in connection with FIGS. 1A-1C.

However, as shown in FIG. 7A, the ESD protection devices 102 of the semiconductor device 700 include dummy gate structures 114a-114c that each include a plurality of discontinuous dummy gate segments 702a-702c, respectively. The discontinuous dummy gate segments 702a of the dummy gate structure 114a may be spaced apart and arranged in the y-direction in the semiconductor device 700, similarly for the discontinuous dummy gate segments 702b of the dummy gate structure 114b and the discontinuous dummy gate segments 702c of the dummy gate structure 114c.

Including discontinuous dummy gate segments 702a-702c for the dummy gate structures 114a-114c, as opposed to a continuous structure that extends in the y-direction, may enable an increased pattern density to be achieved for the masking layer that is used to etch the layers of the dummy gate structures 114a-114c to form the dummy gate structures 114a-114c. The increased pattern density increases the amount of radiation that passes through the masking layer during a photolithography operation to pattern the masking layer, resulting in increased exposure efficiency and, therefore, increased luminous flux. The increased luminous flux decreases the likelihood of underdevelopment of the pattern in the masking layer, which decreases the likelihood of residual masking material (sometimes referred to as photoresist scum) remaining in the masking layer. The reduced likelihood of residual masking material reduces the likelihood that under-etching might otherwise occur because of the residual material blocking an etchant that is used during etching of the layers of the active gate structures 110, the dummy gate structures 112, and the dummy gate structures 114a-114c. Therefore, the inclusion of the discontinuous dummy gate segments 702a-702c for the dummy gate structures 114a-114c reduces the likelihood of defect formation in the dummy gate structures 114a-114c. However, including the continuous structures for the dummy gate structures 114, as in the semiconductor device 100, enables a higher on current (Iₒₙ) for the ESD protection devices 102 to be achieved.

A y-direction distance or spacing (indicated in FIG. 7A as dimension D12) between adjacent dummy gate segments of a dummy gate structure (e.g., between adjacent dummy gate segments 702a of a dummy gate structure 114a, between adjacent dummy gate segments 702b of a dummy gate structure 114b, between adjacent dummy gate segments 702c of a dummy gate structure 114c) may be included in a range of approximately 10 nanometers to approximately 5,000 nanometers. If the y-direction distance between adjacent dummy gate segments of a dummy gate structure is less than approximately 10 nanometers, patterning issues may occur in a masking layer that is used to form the dummy gate segments. The patterning issues may include collapsed sections of the masking layer and/or decreased pattern resolution, among other examples. If the y-direction distance between adjacent dummy gate segments of a dummy gate structure is greater than approximately 5,000 nanometers, the on current of the ESD protection devices 102 may be degraded. If the y-direction distance between adjacent dummy gate segments of a dummy gate structure is included in the range of approximately 10 nanometers to approximately 5,000 nanometers, pattern defects may be reduced and/or minimized, and a high on current for the ESD protection devices 102 may be achieved. However, other values, and ranges other than approximately 10 nanometers to approximately 5,000 nanometers, for the y-direction distance between adjacent dummy gate segments of a dummy gate structure are within the scope of the present disclosure.

A dummy gate segment (e.g., a dummy gate segment 702a, 702b, and/or 702c) may have a y-direction lateral width (indicated in FIG. 7A as dimension D13) that is included in a range of approximately 0.1 microns to approximately 20 microns. If the y-direction lateral width of a dummy gate segment is less than approximately 0.1 microns, patterning issues may occur in a masking layer that is used to form the dummy gate segments. The patterning issues may include collapsed sections of the masking layer and/or decreased pattern resolution, among other examples. If the y-direction lateral width of a dummy gate segment is greater than approximately 20 microns, the dummy gate segment may become structurally unstable and may collapse. If the y-direction lateral width of a dummy gate segment is included in the range of approximately 0.1 microns to approximately 20 microns, pattern defects may be reduced and/or minimized, and a high structural integrity for the dummy gate segment may be achieved. However, other values and ranges, other than approximately 0.1 microns to approximately 20 microns, for the dimension D2 are within the scope of the present disclosure.

As further shown in FIG. 7A, the discontinuous dummy gate segments 702a for the dummy gate structure 114a and the discontinuous dummy gate segments 702c for the dummy gate structure 114c laterally adjacent to the dummy gate segments 702a for the dummy gate structure 114a in the x-direction are staggered in the y-direction. Thus, each discontinuous dummy gate segment 702a is offset in the y-direction relative to the dummy gate segments 702c, and each dummy gate segment 702c is offset in the y-direction relative to the dummy gate segments 702a. Thus, the opposing ends of each discontinuous dummy gate segment 702a do not align in the y-direction with the opposing ends of any of the discontinuous dummy gate segment 702c, and the opposing ends of each discontinuous dummy gate segment 702c do not align in the y-direction with the opposing ends of any of the discontinuous dummy gate segments 702a. Alternatively, if a y-direction width of a discontinuous dummy gate segment 702a is different from a y-direction width of a discontinuous dummy gate segment 702c, a first end of the discontinuous dummy gate segment 702a and a first end of the discontinuous dummy gate segment 702c may be approximately aligned in the y-direction, and a second end of the discontinuous dummy gate segment 702a and a second end of the discontinuous dummy gate segment 702c may be offset in the y-direction.

The discontinuous dummy gate segments 702b for the dummy gate structure 114b and the discontinuous dummy gate segments 702c for the dummy gate structure 114c laterally adjacent to the dummy gate segments 702b for the dummy gate structure 114b in the x-direction are staggered in the y-direction. Thus, each discontinuous dummy gate segment 702b is offset in the y-direction relative to the dummy gate segments 702c, and each dummy gate segment 702c is offset in the y-direction relative to the dummy gate segments 702b. Thus, the opposing ends of each discontinuous dummy gate segment 702b do not align in the y-direction with the opposing ends of any of the discontinuous dummy gate segment 702c, and the opposing ends of each discontinuous dummy gate segment 702c do not align in the y-direction with the opposing ends of any of the discontinuous dummy gate segments 702b. Alternatively, if a y-direction width of a discontinuous dummy gate segment 702b is different from a y-direction width of a discontinuous dummy gate segment 702c, a first end of the discontinuous dummy gate segment 702b and a first end of the discontinuous dummy gate segment 702c may be approximately aligned in the y-direction, and a second end of the discontinuous dummy gate segment 702b and a second end of the discontinuous dummy gate segment 702c may be offset in the y-direction.

The discontinuous dummy gate segments 702c for the dummy gate structure 114c may be located between the discontinuous dummy gate segments 702a for the dummy gate structure 114a and the discontinuous dummy gate segments 702b for the dummy gate structure 114b laterally adjacent to the dummy gate segments 702a for the dummy gate structure 114a in the x-direction. In some implementations, the discontinuous dummy gate segments 702a for the dummy gate structure 114a and the discontinuous dummy gate segments 702b for the dummy gate structure 114b are approximately aligned in the y-direction. In these implementations, the opposing ends of a discontinuous dummy gate segment 702a may be approximately aligned in the y-direction with opposing ends of a discontinuous dummy gate segment 702b, and the opposing ends of a discontinuous dummy gate segment 702b may be approximately aligned in the y-direction with opposing ends of a discontinuous dummy gate segment 702a. Alternatively, one or more discontinuous dummy gate segments 702a may be offset in the y-direction relative to the dummy gate segments 702b, and/or one or more dummy gate segments 702b may be offset in the y-direction relative to the dummy gate segments 702a.

As shown in FIGS. 7B and 7C, the top view arrangement of the discontinuous dummy gate segments 702a-702c of the dummy gate structures 114a-114c results in the different cross-section views along the line A-A and the line B-B. For example, the dummy gate structures 114a and 114b are visible in the cross-section view along the line A-A in FIG. 7B, whereas only the dummy gate structure 114c is visible in the cross-section view along the line B-B in FIG. 7C.

As shown in a detailed top view of the source/drain region 108 in FIG. 7D, the dummy gate segments 702a-702c block portions of the substrate 104 from being doped, resulting in the source/drain region 108 having an overall grid shape. The portions of the substrate 104 that are blocked from being doped correspond to the diffusion regions 138. The diffusion regions 138 are distributed in an array and correspond to portions of the lightly doped implant region 134 having a lower dopant concentration that the source/drain region 108. The source/drain region 108 includes a plurality of implant segments around the diffusion regions 138. Thus, in a top view of the semiconductor device 700, the doped regions (e.g., diffusion regions 138) having a lower dopant concentration than the dopant concentration of the source/drain region 108 are dispersed across the source/drain region 108. In other words, discontinuous segments (e.g., diffusion regions 138) of the lightly doped implant region 134 are interspersed throughout the top view of the source/drain region 108.

As indicated above, FIGS. 7A-7D are provided as examples. Other examples may differ from what is described with regard to FIGS. 7A-7D.

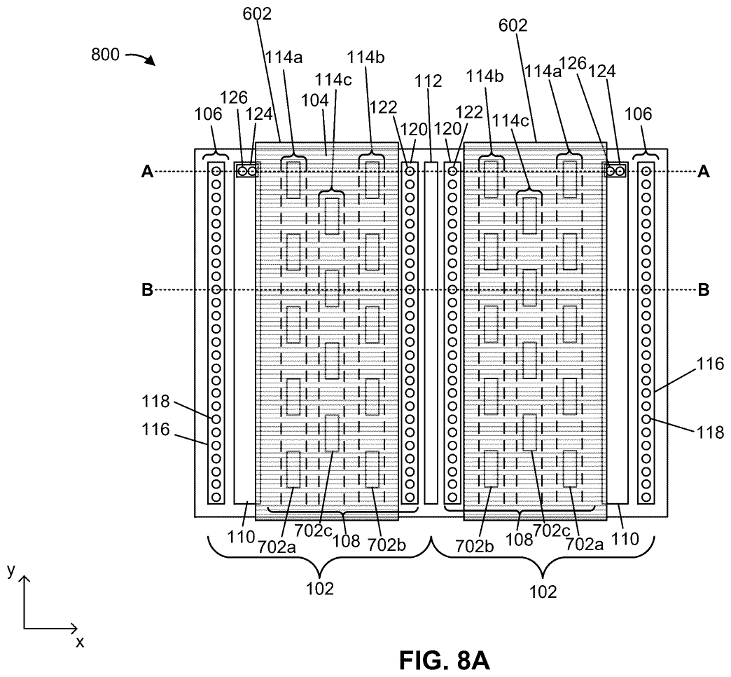

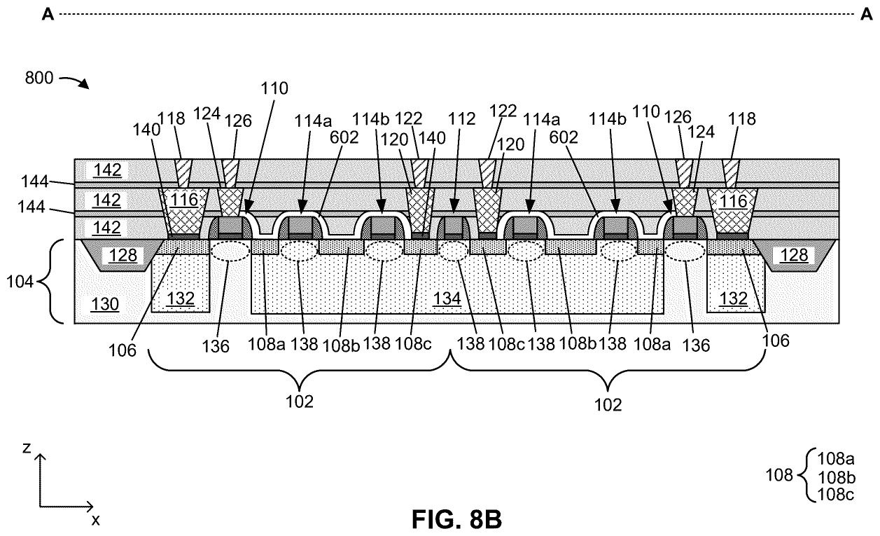

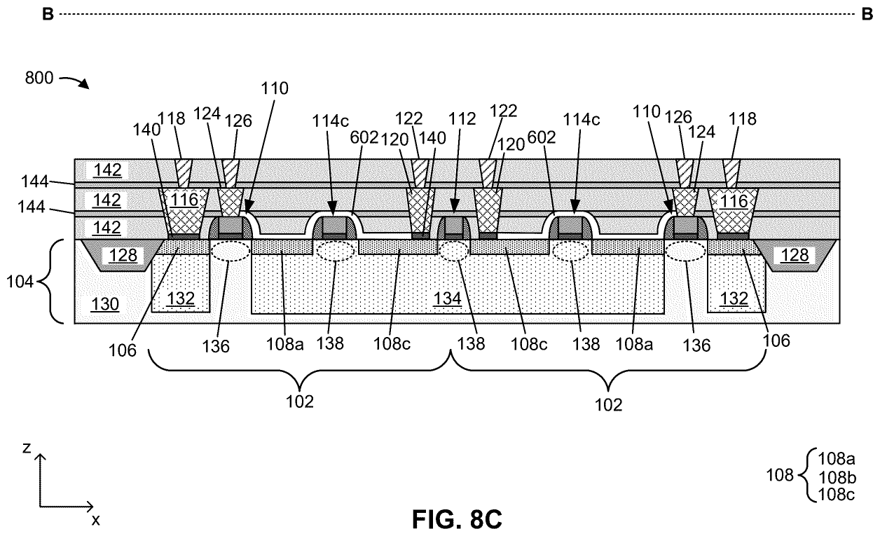

FIGS. 8A-8C are diagrams of an example semiconductor device 800 described herein. FIG. 8A illustrates a top view of the semiconductor device 800. FIG. 8B illustrates a cross-section view of the semiconductor device 800 along the line A-A in FIG. 8A. FIG. 8C illustrates a cross-section view of the semiconductor device 800 along the line B-B in FIG. 8A.

As shown in FIGS. 8A-8C, the semiconductor device 800 includes a similar combination and arrangement of layers and/or structures as the semiconductor device 700 illustrated and described in connection with FIGS. 7A-7C. However, as shown in FIGS. 8A-8C, the ESD protection devices 102 of the semiconductor device 800 further include RPO layers 602 over the dummy gate structures 114a-114c (and the associated discontinuous dummy gate segments 702a-70c) and over a side of the active gate structure 110 facing the source/drain region 108. An RPO layer 602 may include oxide material such as a silicon oxide (SiOₓ such as SiO₂) and/or another dielectric oxide material.

The RPO layer 602 may be formed after formation of the source/drain regions 106 and 108, as described in connection FIGS. 3H and FIGS. 4A-4G. For example, the RPO layer 602 may be deposited over the semiconductor device 800, including over the source/drain regions 106 and 108, over the active gate structures 110, over the dummy gate structures 112, and over the dummy gate structures 114. A patterned masking layer may be formed on the RPO layer 602 and used to etch the RPO layer 602 to remove portions of the RPO layer 602. The remaining portions of the RPO layer 602 may be included over the dummy gate structures 114a-114c (and the associated discontinuous dummy gate segments 702a-70c) and over a side of the active gate structure 110 facing the source/drain region 108.

As indicated above, FIGS. 8A-8C are provided as examples. Other examples may differ from what is described with regard to FIGS. 8A-8C.

FIG. 9 is a diagram of an example semiconductor device 900 described herein. The semiconductor device 900 includes an example of a semiconductor die, an IC chip, or another type of semiconductor device 900 that includes a core circuitry region 902, I/O devices 904, and one or more ESD protection devices 906 and/or 908 included in the signal path between the I/O devices 904 and the core circuitry region 902. The core circuitry region 902 includes the logic circuits, the memory circuits, and/or other functional circuits of the semiconductor device 900. The I/O devices 904 may include contact pads, I/O fanout structures, and/or another type of I/O devices.

The ESD protection devices 906 and 908 may each be implemented by one or more example implementations of semiconductor devices 100, 600, 700, and/or 800 described herein. In some implementations, the ESD protection devices 906 include ggNMOS protection devices and the ESD protection devices 908 include ggPMOS protection devices. In some implementations, the ESD protection devices 908 include ggNMOS protection devices and the ESD protection devices 906 include ggPMOS protection devices. The ESD protection devices 906 and 908 are configured to provide ESD protection for the core circuitry region 902 for the signals transferred between the I/O devices 904 and the core circuitry region 902.

As indicated above, FIG. 9 is provided as an example. Other examples may differ from what is described with regard to FIG. 9.

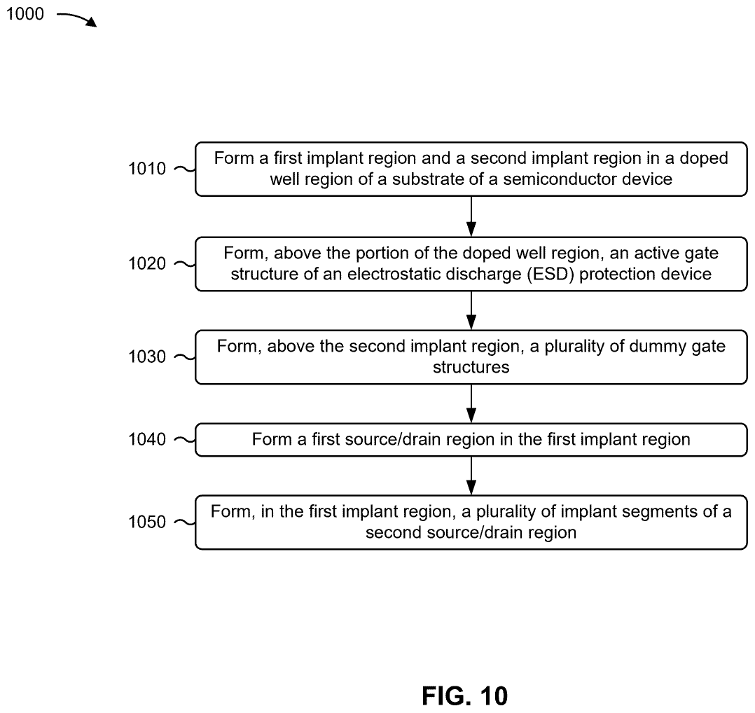

FIG. 10 is a flowchart of an example process 1000 associated with forming an ESD protection device described herein. In some implementations, one or more process blocks of FIG. 10 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 10, process 1000 may include forming a first implant region and a second implant region in a doped well region of a substrate of a semiconductor device (block 1010). For example, one or more semiconductor processing tools may be used to form a first implant region (e.g., a lightly doped implant region 132) and a second implant region (e.g., a lightly doped implant region 134) in a doped well region (e.g., a well region 130) of a substrate (e.g., a substrate 104) of a semiconductor device (e.g., a semiconductor device 100, a semiconductor device 600, a semiconductor device 700, a semiconductor device 800, an ESD protection device 906, an ESD protection device 908), as described herein. In some implementations, a portion of the doped well region is located laterally between the first implant region and the second implant region.

As further shown in FIG. 10, process 1000 may include forming, above the portion of the doped well region, an active gate structure of an ESD protection device (block 1020). For example, one or more semiconductor processing tools may be used to form, above the portion of the doped well region, an active gate structure (e.g., an active gate structure 110) of ESD protection device (e.g., an ESD protection device 102), as described herein.

As further shown in FIG. 10, process 1000 may include forming, above the second implant region, a plurality of dummy gate structures (block 1030). For example, one or more semiconductor processing tools may be used to form, above the second implant region, a plurality of dummy gate structures (e.g., dummy gate structures 114, a dummy gate structure 112), as described herein.

As further shown in FIG. 10, process 1000 may include forming a first source/drain region in the first implant region (block 1040). For example, one or more semiconductor processing tools may be used to form a first source/drain region (e.g., a source/drain region 106) in the first implant region, as described herein.

As further shown in FIG. 10, process 1000 may include forming, in the first implant region, a plurality of implant segments of a second source/drain region (block 1050). For example, one or more semiconductor processing tools may be used to form, in the first implant region, a plurality of implant segments (e.g., implant segments 108a-108c) of a second source/drain region (e.g., a source/drain region 108), as described herein. In some implementations, the plurality of implant segments are formed between the plurality of dummy gate structures and between the active gate structure and a dummy gate structure of the plurality of dummy gate structures.

Process 1000 may include additional implementations, such as any single implementation or any combination of implementations described below and/or in connection with one or more other processes described elsewhere herein.

In a first implementation, process 1000 includes forming a dielectric layer (e.g., a dielectric layer 402) on the substrate, where forming the active gate structure and the plurality of dummy gate structures includes forming the active gate structure and the plurality of dummy gate structures on the dielectric layer, and process 1000 includes etching the dielectric layer based on the active gate structure and the plurality of dummy gate structures to form respective gate dielectric layers (e.g., gate dielectric layers 202) for the active gate structure and each of the plurality of dummy gate structures.

In a second implementation, alone or in combination with the first implementation, process 1000 includes forming a masking layer (e.g., a masking layer 404) over the active gate structure and over the plurality of dummy gate structures, and etching the masking layer to remove the masking layer from the plurality of dummy gate structures, where the masking layer remains over the active gate structure, and where etching the dielectric layer includes etching the dielectric layer based on the masking layer over the active gate structure to form the gate dielectric layer for the active gate structure.

In a third implementation, alone or in combination with one or more of the first and second implementations, etching the dielectric layer includes etching the dielectric layer such that the gate dielectric layer of the active gate structure has a greater lateral width (dimension D9) than a lateral width (dimension D10, dimension D11) of the gate dielectric layers for each of the plurality of dummy gate structures.

In a fourth implementation, alone or in combination with one or more of the first through third implementations, forming the plurality of dummy gate structures includes forming the plurality of dummy gate structures such that the plurality of dummy gate structures each extend in a first direction (e.g., a y-direction) that is approximately parallel to the active gate structure and such that the plurality of dummy gate structures are arranged in a second direction (e.g., an x-direction) that is approximately orthogonal to the active gate structure.

In a fifth implementation, alone or in combination with one or more of the first through fourth implementations, the plurality of implant segments of the second source/drain region each extend in the first direction.

In a sixth implementation, alone or in combination with one or more of the first through fifth implementations, process 1000 includes forming a source/drain contact on an implant segment, of the plurality of implant segments, that is the furthest of the plurality of implant segments away from the active gate structure.

Although FIG. 10 shows example blocks of process 1000, in some implementations, process 1000 includes additional blocks, fewer blocks, different blocks, or differently arranged blocks than those depicted in FIG. 10. Additionally, or alternatively, two or more of the blocks of process 1000 may be performed in parallel.

In this way, a semiconductor device includes an ESD protection device that includes an active gate structure and a plurality of dummy gate structures between the active gate structure and a source/drain region of the ESD protection device. The dummy gate structures are used as a self-aligned implant mask when forming the source/drain region. The dummy gate structures enable the source/drain region to be formed as a plurality of implant segments that are spaced apart in a substrate of the semiconductor device. The space between the implant segments provides areas in the substrate in which dopants from the implant segments may diffuse from subsequent manufacturing operations for the semiconductor device. Thus, the dopants diffuse into the substrate across a greater area of the substrate than if the source/drain region were a continuous implant region, reducing the dopant concentration from the implant segments in the substrate. This reduces the build-up and concentration of dopants near the active gate structure, which reduces the strength of the electric field near the active gate structure. The reduced strength of the electric field near the active gate structure lessens the damage caused to the ESD protection device across multiple ESD events, thereby increasing the operational life of the ESD protection device.

As described in greater detail above, some implementations described herein provide a semiconductor device. The semiconductor device includes a substrate that includes a doped well region having a first dopant type. The semiconductor device includes an ESD protection device in the substrate. The ESD protection device includes an implant region, in the doped well region, having a second dopant type. The ESD protection device includes an active gate structure above the substrate and adjacent to an edge of the implant region. The ESD protection device includes a first source/drain region adjacent to a first side of the active gate structure. The ESD protection device includes a second source/drain region adjacent to a second side of the active gate structure opposing the first side. The second source/drain region includes a plurality of implant segments, each implant segment including the second dopant type. The ESD protection device includes a first source/drain contact coupled to the first source/drain region. The ESD protection device includes a second source/drain contact coupled to an implant segment of the plurality of implant segments.

As described in greater detail above, some implementations described herein provide a method. The method includes forming a first implant region and a second implant region in a doped well region of a substrate of a semiconductor device. A portion of the doped well region is located laterally between the first implant region and the second implant region. The method includes forming, above the portion of the doped well region, an active gate structure of an ESD protection device. The method includes forming, above the second implant region, a plurality of dummy gate structures. The method includes forming a first source/drain region in the first implant region. The method includes forming, in the first implant region, a plurality of implant segments of a second source/drain region, where the plurality of implant segments are formed between the plurality of dummy gate structures and between the active gate structure and a dummy gate structure of the plurality of dummy gate structures.

As described in greater detail above, some implementations described herein provide a semiconductor device. The semiconductor device includes a doped well region having a first dopant type. The semiconductor device includes an ESD protection device. The ESD protection device includes an implant region, in the doped well region, having a second dopant type. The ESD protection device includes an active gate structure adjacent to an edge of the implant region. The ESD protection device includes a first source/drain region adjacent to a first side of the active gate structure. The ESD protection device includes a second source/drain region adjacent to a second side of the active gate structure opposing the first side. The ESD protection device includes a first source/drain contact coupled to the first source/drain region. The ESD protection device includes a second source/drain contact coupled to second source/drain region. The ESD protection device includes a plurality of dummy gate structures above the implant region. The plurality of dummy gate structures are located laterally between the active gate structure and the second source/drain contact.

The terms “approximately” and “substantially” can indicate a value of a given quantity that varies within 5% of the value (e.g., +1%, +2%, +3%, +4%, +5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate comprising a doped well region including a first dopant type; and
an electrostatic discharge (ESD) protection device in the substrate, comprising:
an implant region, in the doped well region, including a second dopant type;
an active gate structure above the substrate and adjacent to an edge of the implant region;
a first source/drain region adjacent to a first side of the active gate structure;
a second source/drain region adjacent to a second side of the active gate structure opposing the first side,
wherein the second source/drain region comprises a plurality of implant segments, each implant segment including the second dopant type;
a first source/drain contact coupled to the first source/drain region; and
a second source/drain contact coupled to an implant segment of the plurality of implant segments.

2. The semiconductor device of claim 1, wherein the active gate structure extends in a first lateral direction in the semiconductor device; and
wherein the plurality of implant segments are arranged in a second lateral direction in the semiconductor device approximately orthogonal to the first lateral direction.

3. The semiconductor device of claim 2, wherein the plurality of implant segments are arranged in the second lateral direction between the active gate structure and a dummy gate structure adjacent to the second source/drain contact.

4. The semiconductor device of claim 1, wherein, in a top view of the semiconductor device, portions of the implant segment are included between the plurality of implant segments of the second source/drain region.

5. The semiconductor device of claim 1, wherein the ESD protection device further comprises:
a plurality of dummy gate structures above the implant region,
wherein each of the plurality of dummy gate structures is located between adjacent implant segments of the plurality of implant segments.

6. The semiconductor device of claim 5, wherein each of plurality of dummy gate structures extends in a same direction as the active gate structure; and
wherein the plurality of dummy gate structures are approximately parallel to each other.

7. The semiconductor device of claim 5, wherein at least one of the plurality of dummy gate structures continuously extends between a first end of the active gate structure and a second end of the active gate structure opposing the first end.

8. The semiconductor device of claim 5, wherein at least one of the plurality of dummy gate structures comprises a plurality of dummy gate segments that are arranged between a first end of the active gate structure and a second end of the active gate structure opposing the first end.

9. A method, comprising:
forming a first implant region and a second implant region in a doped well region of a substrate of a semiconductor device,
wherein a portion of the doped well region is located laterally between the first implant region and the second implant region;
forming, above the portion of the doped well region, an active gate structure of an electrostatic discharge (ESD) protection device;
forming, above the second implant region, a plurality of dummy gate structures;
forming a first source/drain region in the first implant region; and
forming, in the first implant region, a plurality of implant segments of a second source/drain region,
wherein the plurality of implant segments are formed between the plurality of dummy gate structures and between the active gate structure and a dummy gate structure of the plurality of dummy gate structures.

10. The method of claim 9, further comprising forming a dielectric layer on the substrate;
wherein forming the active gate structure and the plurality of dummy gate structures comprises forming the active gate structure and the plurality of dummy gate structures on the dielectric layer; and
wherein the method further comprises etching the dielectric layer based on the active gate structure and the plurality of dummy gate structures to form respective gate dielectric layers for the active gate structure and each of the plurality of dummy gate structures.

11. The method of claim 10, further comprising forming a masking layer over the active gate structure and over the plurality of dummy gate structures; and
etching the masking layer to remove the masking layer from the plurality of dummy gate structures,
wherein the masking layer remains over the active gate structure, and
wherein etching the dielectric layer comprises etching the dielectric layer based on the masking layer over the active gate structure to form the gate dielectric layer for the active gate structure.

12. The method of claim 10, wherein etching the dielectric layer comprises:
etching the dielectric layer such that the gate dielectric layer of the active gate structure has a greater lateral width than a lateral width of the gate dielectric layers for each of the plurality of dummy gate structures.

13. The method of claim 9, wherein forming the plurality of dummy gate structures comprises forming the plurality of dummy gate structures such that the plurality of dummy gate structures each extend in a first direction that is approximately parallel to the active gate structure and such that the plurality of dummy gate structures are arranged in a second direction that is approximately orthogonal to the active gate structure.

14. The method of claim 13, wherein the plurality of implant segments of the second source/drain region each extend in the first direction.

15. The method of claim 9, further comprising forming a source/drain contact on an implant segment, of the plurality of implant segments, that is the furthest of the plurality of implant segments away from the active gate structure.

16. A semiconductor device, comprising:
a doped well region including a first dopant type; and
an electrostatic discharge (ESD) protection device, comprising:
an implant region, in the doped well region, including a second dopant type;
an active gate structure adjacent to an edge of the implant region;
a first source/drain region adjacent to a first side of the active gate structure;
a second source/drain region adjacent to a second side of the active gate structure opposing the first side;
a first source/drain contact coupled to the first source/drain region;
a second source/drain contact coupled to second source/drain region; and
a plurality of dummy gate structures above the implant region,
wherein the plurality of dummy gate structures are located laterally between the active gate structure and the second source/drain contact.

17. The semiconductor device of claim 16, wherein the plurality of dummy gate structures comprises a first dummy gate structure adjacent to a first of the second source/drain contact; and
wherein the semiconductor device further comprises a second dummy gate structure adjacent to a second side of the second source/drain contact opposing the first side,
wherein the second dummy gate structure is located above the implant region.

18. The semiconductor device of claim 17, wherein a gate dielectric layer of the active gate structure has a first lateral width;
wherein a gate structure of the first dummy gate structure has a second lateral width; and
wherein the first lateral width is greater than the second lateral width.

19. The semiconductor device of claim 16, wherein a first dummy gate structure of the plurality of dummy gate structures comprises a first plurality of dummy gate segments arranged in a direction approximately parallel to the active gate structure;
wherein a second dummy gate structure of the plurality of dummy gate structures comprises a second plurality of dummy gate segments arranged in the direction approximately parallel to the active gate structure; and
wherein the second plurality of dummy gate segments are staggered relative to the first plurality of discontinuous dummy gate segments in the direction approximately parallel to the active gate structure.

20. The semiconductor device of claim 19, wherein a third dummy gate structure of the plurality of dummy gate structures comprises a third plurality of dummy gate segments arranged in the direction approximately parallel to the active gate structure; and
wherein each of the first plurality of dummy gate segments is aligned with a respective one of the third plurality of dummy gate segments in the direction approximately parallel to the active gate structure.
